(19) United States
(12) Patent Application Publication
(10) Pub. No.: US 2011/0233681 A1
(43) Pub. Date: Sep. 29, 2011

(54) SEMICONDUCTOR DEVICE AND METHOD OF MANUFACTURING THE SAME

(76) Inventor: Kouji MATSUO, Kanagawa (JP)

(21) Appl. No.: 13/049,418

(22) Filed: Mar. 16, 2011

(30) Foreign Application Priority Data
Mar. 24, 2010 (JP) 2010-068148

(51) Int. Cl. H01L 27/092; H01L 21/20

(52) U.S. Cl. 257/369; 438/479; 257/E27.062; 257/E21.09

(57) ABSTRACT

According to one embodiment, a semiconductor device includes: columnar gate electrodes that are separated from one another in a row on a semiconductor substrate; a gate insulating film that covers side faces of the columnar gate electrodes; a first semiconductor layer of a first conductivity type that is formed on the semiconductor substrate between the adjacent columnar gate electrodes; a insulating layer that is formed on the first semiconductor layer between the adjacent columnar gate electrodes; and a second semiconductor layer of a second conductivity type, which is different from the first conductivity type, that is formed on the insulating layer between the adjacent columnar gate electrodes. In the semiconductor device, a first MOSFET of the first conductivity type that uses the first semiconductor layer as a channel is formed, and a second MOSFET of the second conductivity type that uses the second semiconductor layer as a channel is formed.

### CROSS-REFERENCE TO RELATED APPLICATIONS

This application is based upon and claims the benefit of priority from the prior Japanese Patent Application No. 2010-68148, filed on Mar. 24, 2010; the entire contents of which are incorporated herein by reference.

### FIELD

Embodiments described herein relate generally to a semiconductor device and a method of manufacturing the same.

### BACKGROUND

As the structure of a double-gate MOSFET, besides a structure in which a channel is formed using the surface of the principal face of the semiconductor body and gate electrodes are formed on the top face and the bottom face, an FINFET structure is proposed in which a channel is formed so as to be perpendicular (in a fin shape) to the principal face of the semiconductor body and gates are formed on both sides of the channel. However, in regard with a MOSFET having a conventional FINFET structure, i.e., a so-called MOSFET having a double-gate structure, it involves a problem that there exists a portion with high parasitic resistance in the source/drain region due to the margin of gate patterns to be joined.

To solve such a problem, there has been already proposed a semiconductor device having drain and source regions free from the problem of the parasitic resistance by forming a columnar gate electrode as part of the gate electrode of the semiconductor device having the double-gate structure and forming a channel in a self-aligned manner.

On the other hand, there have been made many attempts to lower the price of an LSI by increasing the degree of integration of an MISFET circuit by forming a plurality of MISFET (MOSFET) elements in a small area. A representative method of increasing the degree of integration is the downscaling of an element. However, there is a physical limit to the downscaling. Accordingly, an alternative method is proposed in which the area of an element is reduced by stacking an n-type MISFET and a p-type MISFET.

According to this method, an n-type FET is formed first by using a general MOSFET forming method and then a p-type FET is formed thereon by a general forming method, thereby realizing a stacked structure. This allows the decrease in the area of an element of a logic circuit to 70% or below. However, this method requires for photolithography processes for forming element regions and gate electrodes to be performed respectively for n-type FETs and p-type FETs, which results in the increase in the number of the processes twice as compared with a general CMOSFET manufacturing method. That is, this method is problematic in incurring the increased cost for the photolithography process.

### BRIEF DESCRIPTION OF THE DRAWINGS

FIGS. 1A to 1C are cross-sectional views taken along lines A-A′ and and a top view illustrating a semiconductor device according to a first embodiment of the invention;

FIGS. 2A to 2C are cross-sectional views taken along lines A-A′ and B-B′ and a top view illustrating a method of manufacturing a semiconductor device according to the first embodiment;

FIGS. 3A to 3C are cross-sectional views taken along lines A-A′ and B-B′ and a top view, following FIGS. 2A to 2C, illustrating the method of manufacturing a semiconductor device according to the first embodiment;

FIGS. 4A to 4C are cross-sectional views taken along lines A-A′ and B-B′ and a top view, following FIGS. 3A to 3C, illustrating the method of manufacturing a semiconductor device according to the first embodiment;

FIGS. 5A to 5C are cross-sectional views taken along lines A-A′ and B-B′ and a top view, following FIGS. 4A to 4C, illustrating the method of manufacturing a semiconductor device according to the first embodiment;

FIGS. 6A to 6C are cross-sectional views taken along lines A-A′ and B-B′ and a top view, following FIGS. 5A to 5C, illustrating the method of manufacturing a semiconductor device according to the first embodiment;

FIGS. 7A to 7C are cross-sectional views taken along lines A-A′ and B-B′ and a top view, following FIGS. 6A to 6C, illustrating the method of manufacturing a semiconductor device according to the first embodiment;

FIGS. 8A to 8C are cross-sectional views taken along lines A-A′ and El-B′ and a top view, following FIGS. 7A to 7C, illustrating the method of manufacturing a semiconductor device according to the first embodiment;

FIGS. 9A to 9C are cross-sectional views taken along lines A-A′ and B-B′ and a top view, following FIGS. 8A to 8C, illustrating the method of manufacturing a semiconductor device according to the first embodiment;

FIGS. 10A to 10C are cross-sectional views taken along lines A-A′ and B-B′ and a top view, following FIGS. 9A to 9C, illustrating the method of manufacturing a semiconductor device according to the first embodiment;

FIGS. 11A to 11C are cross-sectional views taken along lines A-A′ and B-B′ and a top view, following FIGS. 10A to 10C, illustrating the method of manufacturing a semiconductor device according to the first embodiment;

FIGS. 12A to 12C are cross-sectional views taken along lines A-A′ and B-B′ and a top view, following FIGS. 11A to 11C, illustrating the method of manufacturing a semiconductor device according to the first embodiment;

FIGS. 13A to 13C are cross-sectional views taken along lines A-A′ and B-B′ and a top view, following FIGS. 12A to 12C, illustrating the method of manufacturing a semiconductor device according to the first embodiment;

FIGS. 14A to 14C are cross-sectional views taken along lines A-A′ and B-B′ and a top view, following FIGS. 13A to 13C, illustrating the method of manufacturing a semiconductor device according to the first embodiment;

FIGS. 15A to 15C are cross-sectional views taken along lines A-A′ and B-B′ and a top view, following FIGS. 14A to 14C, illustrating the method of manufacturing a semiconductor device according to the first embodiment;

FIGS. 16A to 16C are cross-sectional views taken along lines A-A′ and B-B′ and a top view, following FIGS. 15A to 15C, illustrating the method of manufacturing a semiconductor device according to the first embodiment;

FIGS. 17A to 17C are cross-sectional views taken along lines A-A′ and B-B′ and a top view, following FIGS. 16A to 16C, illustrating the method of manufacturing a semiconductor device according to the first embodiment;

FIGS. 18A to 18C are cross-sectional views taken along lines A-A′ and B-B′ and a top view, following FIGS. 17A to 17C, illustrating the method of manufacturing a semiconductor device according to the first embodiment;

FIGS. 19A to 19C are cross-sectional views taken along lines A-A′ and B-B′ and a top view, following FIGS. 18A to 18C, illustrating the method of manufacturing a semiconductor device according to the first embodiment;

FIGS. 20A to 20C are cross-sectional views taken along lines A-A′ and B-B′ and a top view, following FIGS. 19A to 19C, illustrating the method of manufacturing a semiconductor device according to the first embodiment;

FIGS. 21A to 21C are cross-sectional views taken along lines A-A′ and B-B′ and a top view, following FIGS. 20A to 20C, illustrating the method of manufacturing a semiconductor device according to the first embodiment;

FIGS. 22A to 22C are cross-sectional views taken along lines A-A′ and B-B′ and a top view, following FIGS. 21A to 21C, illustrating the method of manufacturing a semiconductor device according to the first embodiment;

FIGS. 23A to 23C are cross-sectional views taken along lines A-A′ and B-B′ and a top view, following FIGS. 22A to 22C, illustrating the method of manufacturing a semiconductor device according to the first embodiment;

FIG. 24 is a diagram illustrating the designed size of a single MOSFET constituting a conventional CMOS;

FIG. 25 is a diagram illustrating the designed size of a stacked structure of an n-type MOSFET and a p-type MOSFET according to the first embodiment;

FIG. 26 is a top view illustrating a semiconductor device constituting a NAND circuit according to a second embodiment of the invention;

FIG. 27 is a circuit diagram of a NAND circuit according to the second embodiment;

FIG. 28 is a top view illustrating a semiconductor device constituting a NOR circuit according to a third embodiment of the invention;

FIG. 29 is a circuit diagram of a NQR circuit according to the third embodiment;

FIG. 30 is a top view illustrating a semiconductor device constituting an SRAM cell circuit according to a fourth embodiment of the invention;

FIG. 31 is a cross-sectional view taken along line A-A′, which illustrates a semiconductor device constituting an SRAM cell circuit according to the fourth embodiment;

FIG. 32 is a cross-sectional view taken along line B-B′, which illustrates a semiconductor device constituting an SRAM cell circuit according to the fourth embodiment;

FIG. 33 is a circuit diagram of an SRAM cell circuit according to the fourth embodiment; and

FIG. 34 is a diagram illustrating the designed size of a semiconductor device constituting an SRAM cell circuit according to the fourth embodiment.

### DETAILED DESCRIPTION

In general, according to one embodiment, a semiconductor device includes a first group of a plurality of columnar gate electrodes formed being separated from one another, each in a row, on a semiconductor substrate, a first gate insulating film that covers side faces of each of the plurality of columnar gate electrodes of the first group, a first semiconductor layer of a first conductivity type that is formed on the semiconductor substrate between the columnar gate electrodes of the first group that are adjacent to each other, a first insulating layer that is formed on the first semiconductor layer disposed between the adjacent columnar gate electrodes of the first group, and a second semiconductor layer of a second conductivity type different from the first conductivity type, which is formed on the first insulating layer disposed between the adjacent columnar gate electrodes of the first group. In the semiconductor device, a first MOSFET of the first conductivity type that uses the first semiconductor layer as a channel is formed, and a second MISFET of the second conductivity type that uses the second semiconductor layer as a channel is formed.

Exemplary embodiments of the semiconductor device and a method of manufacturing of the semiconductor device will be explained below in detail with reference to the accompanying drawings. The invention is not limited to the following embodiments.

### First Embodiment

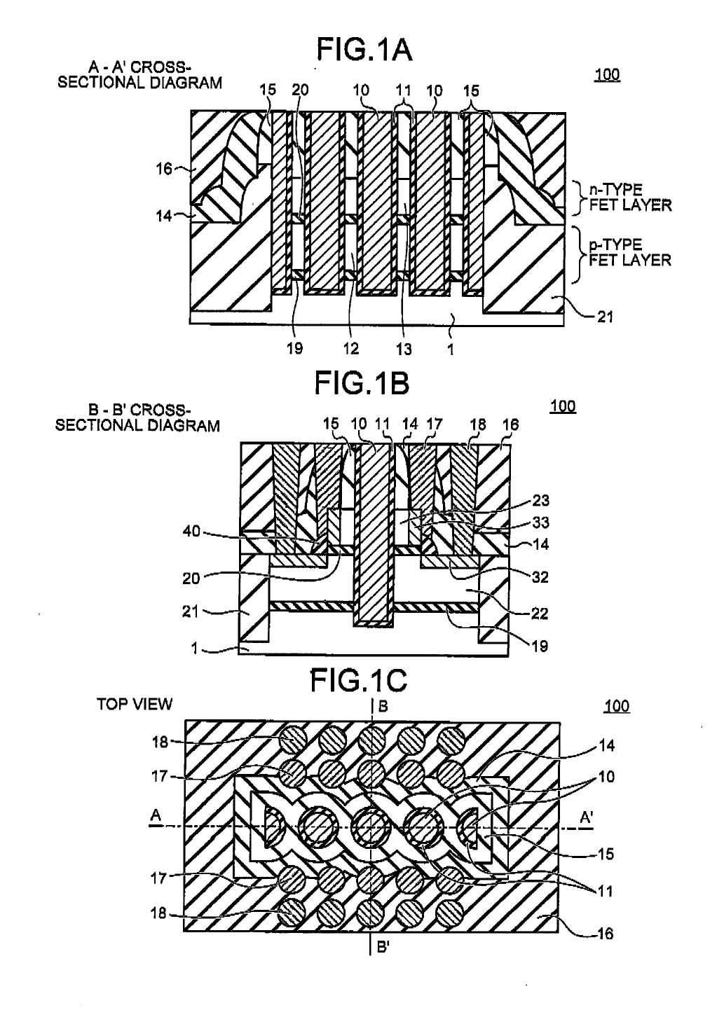

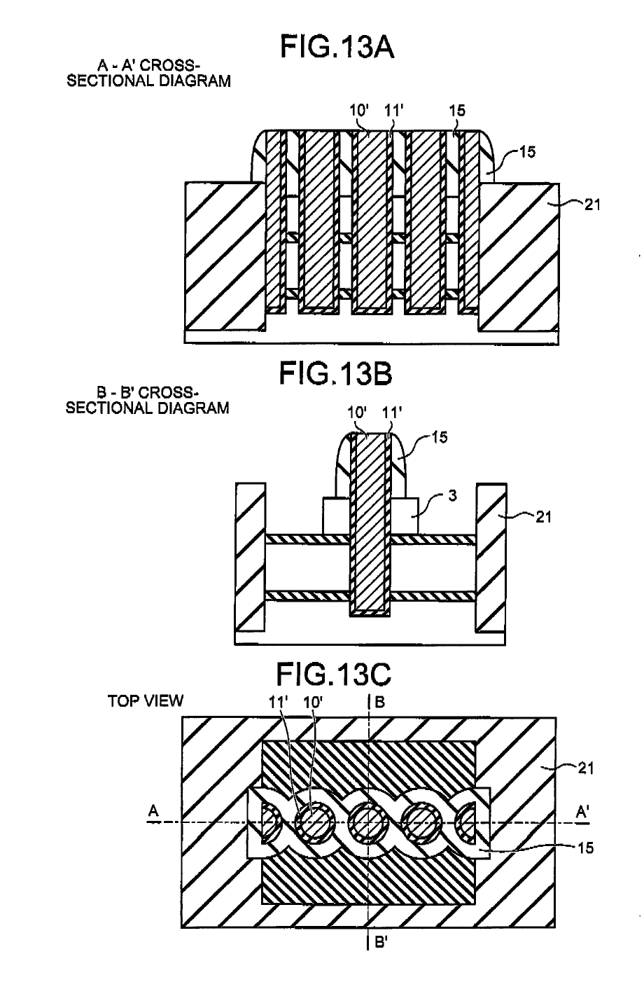

FIGS. 1A to 1C show a semiconductor device 100 according to a first embodiment of the invention. FIG. 1C is a top view and FIGS. 1A and 13 are cross-sectional views. The semiconductor device 100 illustrated in FIGS. 1A to 1C has a stacked structure of an MISFET, in which a p-type FET and an n-type FET are stacked. A gate electrode 10 has a cylindrical shape that passes through a channel 12 of the p-type FET and a channel 13 of the n-type FET. The columnar gate electrode 10 passes through the n-type FET and the p-type FET and thus is common to the n-type FET and the p-type FET. Accordingly, the basic structure of an inverter circuit is formed at the time when this structure is formed.

Hereinafter, the configuration of the semiconductor device 100 illustrated in FIGS. 1A to 1C will be described in more detail. A diagram of the semiconductor device 100 viewed from the top is the top view (FIG. 1C), and gate electrodes 10 that are columnar electrodes form a row. The periphery of each gate electrode 10 is covered with a gate insulating film 11, and the entire columnar row including the gate insulating films 11 is further covered with a side-wall (SW) insulating film 15 formed from SiN or the like. In addition, the outer side thereof is covered with a barrier SiN film 14, and the periphery thereof is buried in an interlayer SiO₂ film 16 and is planarized.

In addition, in order to form rows that are parallel to the row of the gate electrodes 10, a row of contacts (hereinafter, referred to as n-type FET contacts) 17 that are in contact with the source and the drain of the n-type MOSFET, and a row of contacts (hereinafter, referred to as a p-type FET contact) 18, which are in contact with the source and the drain of the p-type MOSFET, constituting a row that is located on the outer side thereof are aligned.

The cross-sectional view of the semiconductor device 100 that is taken along line A-A′ shown in FIG. 1C is FIG. 1A, and the cross-sectional view of the semiconductor device 100 that is taken along line B-B′ is FIG. 1B. As can be understood from FIG. 1A, a channel layer 12 of the p-type FET and a channel layer 13 of the n-type FET are formed in the lower layer and the upper layer, respectively with being interposed between a plurality of the columnar gate electrodes 10 that are formed in a row on the semiconductor substrate 1 so as to be separated from each other and the gate insulating film 11 covering the gate electrodes 10. In FIG. 1A, the direction vertical to the sheet surface is set as the direction of the channel length.

Thermally-oxidized films 19 and 20 formed from SiO₂ are formed between the semiconductor (silicon) substrate 1 and the channel layer 12 of the p-type FET and between the channel layer 12 of the p-type FET and the channel layer 13 of the n-type FET and separate each layer. In addition, below the barrier SiN film 14 and the side-wall insulating film 15, a shallow trench isolation (STI) layer 21 formed from SiO₂ is formed.

Next, as shown in FIG. 1B, it can be understood that the same layer as the channel layer 12 of the p-type FET is a p+ diffusion layer 22, and the same layer as the channel layer 13 of the n-type FET channel is an n+ diffusion layer 23. In addition, in the upper portion of the p+ diffusion layer 22, a p-type FET source (S)/drain(D) silicide layer 32 is formed, and an n-type FET source (S)/drain (D) silicide layer 33 is formed on the side face of the n+ diffusion layer 23.

The p-type FET S/D silicide layer 32 is connected to the p-type FET contact 18, the n-type FET S/D silicide layer 33 is connected to the n-type FET contact 17, and the p-type FET S/D silicide layer 32 and the n-type FET S/D silicide layer 33 function to decrease the resistance through Schottky junction. In addition, in order to prevent the n-type FET contact 17 from being brought into contact with the p-type FET region, a side wall oxide film (SiO₂) 40 that is used as a contact stopper is formed as well.

In other words, in the stacked structure of the p-type and n-type MOSFETs, as the connection regions of the diffusion layers of the source and the drain, the n-type MOSFET located in the upper layer has a connection region 33 on the side face, and the p-type MOSFET located in the lower layer has a connection region 32 on the top face. In addition, the element region of the n-type MOSFET located in the upper layer is smaller than that of the p-type MOSFET located in the lower layer.

As described above, the semiconductor device 100 includes a plurality of the columnar gate electrodes 10 of the first group that is formed in a row on the semiconductor substrate 1 so as to be separated from each other; a p-type (first conductivity type) channel layer 12 (a first semiconductor layer) formed between two columnar gate electrodes 10 adjacent to each other on the semiconductor substrate 1; a thermally-oxidized film 20 (a first insulating layer) that is formed between the two columnar gate electrodes 10 on the channel layer 12; and an n-type (a second conductivity type) channel layer 13 (a second semiconductor layer) that is formed between the two columnar gate electrodes 10 on the thermally-oxidized film 20. Accordingly, a structure is formed in which the p-type MOSFET (a first MOSFET) having the channel layer 12 that shares the columnar gate electrodes 10 and the n-type MOSFET (a second MOSFET) having the channel layer 13 are stacked.

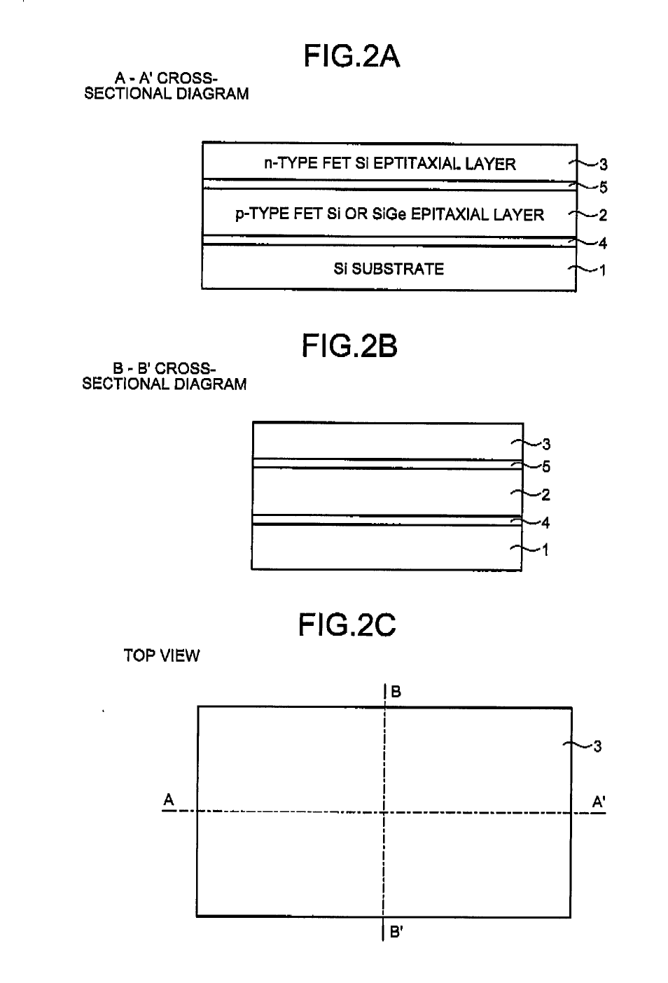

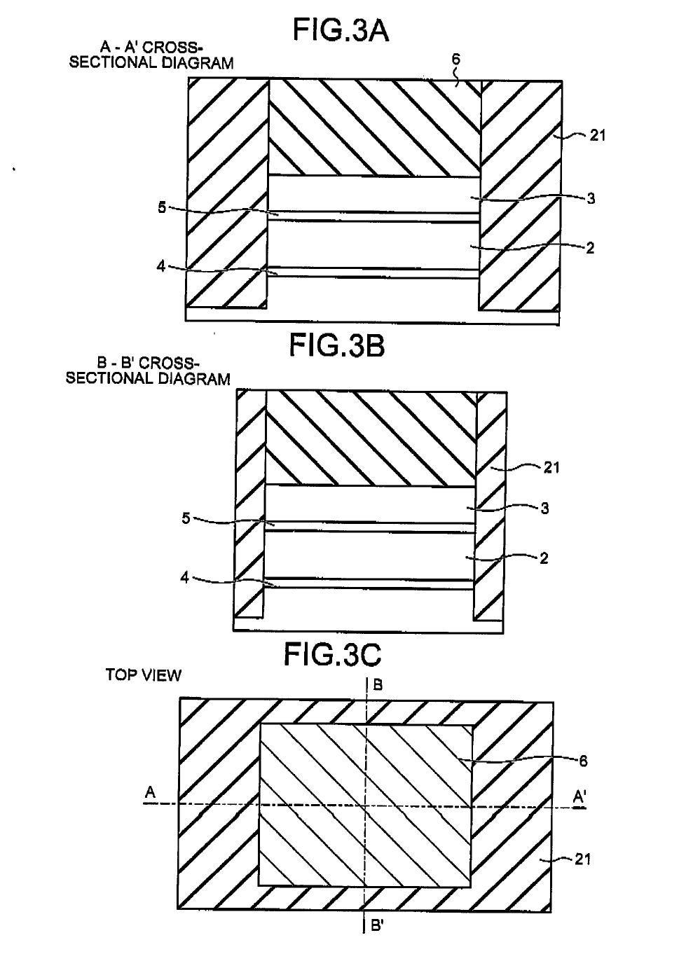

The method of manufacturing the semiconductor device 100 illustrated in FIGS. 1A to 1C will be described below with reference to FIGS. 2A to 2C through FIGS. 23A to 23C. First, as illustrated in the cross-sectional view (FIG. 2A), which is taken along line A-A′, of FIG. 2C as a top view and the cross-sectional view (FIG. 2B), which is taken along line B-B′, of FIG. 2C, a SiGe layer 4 having a Ge density of 30% or more is formed so as to have a thickness of about 10 nm as a film on a Si substrate 1 by using epitaxial technology. In FIGS. 3A to 3C to FIGS. 23A to 23C described below, a partial diagram A is a cross-sectional view, which is taken along line A-A′, of Fig. C as a top view, and a partial diagram B is a cross-sectional view, which is taken along line B-B′, of Fig. C as the top view.

Furthermore, continuously, a Si layer 2 that becomes the channel region of a p-type FET or a SiGe layer 2 containing about 30% or less Ge is formed as a film, for example, so as to have a thickness of about 100 nm through epitaxial growth. In addition, continuously, a SiGe layer 5 having a high density of 30% or more Ge and a Si layer 3 that becomes the channel region of an n-type FET are epitaxially grown, for example, so as to have a thickness of about 50 nm. It is preferable that this film structure is formed at a time inside an epitaxial deposition apparatus. The SiGe layers 4 and 5 are formed by carrying out consistent epitaxial growth continuing from the growth of the SiGe (or Si) layer 2 and the Si layer 3.

In addition, in consideration of the difference between the carrier mobilities of the p-type and the n-type, in order to form the inverter structure, the film thickness of the Si or SiGe layer 2 that becomes the channel region of the p-type FET later is formed so as to be generally thicker than that of the Si layer 3 that becomes the channel region of the n-type FET later. In other words, the width of the Si or SiGe layer 2 that becomes the channel region of the p-type FET in the extension direction (the direction perpendicular to the sheet surface of FIG. 2C) of the columnar gate electrodes 10 is wider than that of the width of the Si layer 3 that becomes the channel region of the n-type FET in the extension direction (the direction perpendicular to the sheet surface of FIG. 2C) of the columnar gate electrodes 10.

Next, as illustrated in FIGS. 3A to 3C, after, for example, a SiN film 6 that becomes a hard mask for processing is formed as a film, an STI region 21 that is formed from SiO₂ is formed. This technology is a technology known as a method of forming a conventional single-layer MOSFET structure.

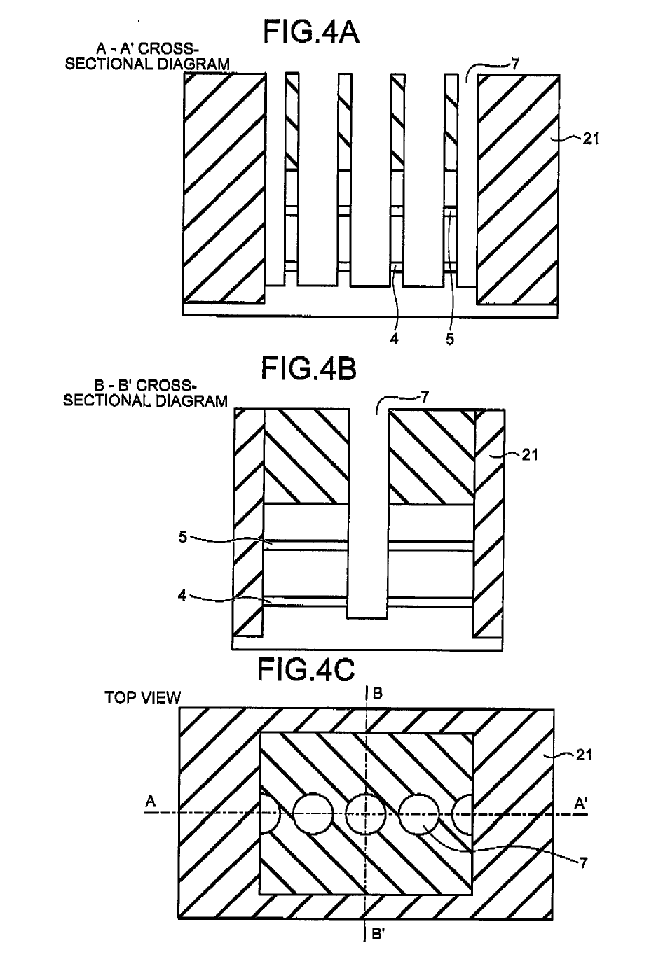

Next, as illustrated in FIGS. 4A to 4C, holes (gate holes) 7 used for burying the gate electrodes later are formed by using lithography technology and dry etching technology (for example, a reactive ion etching (RIE) or the like).

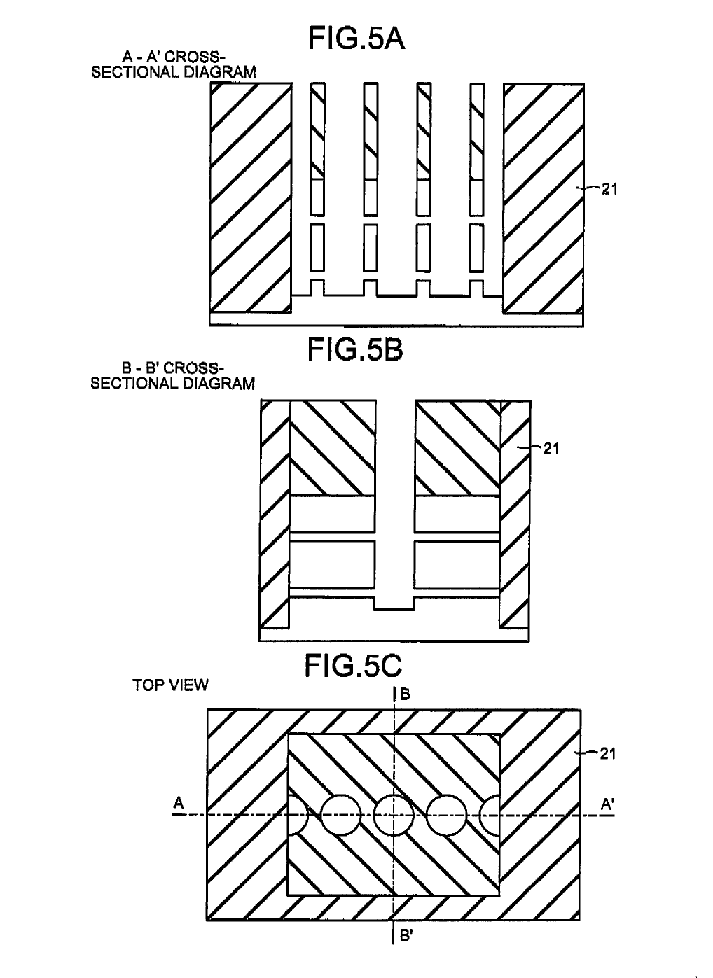

Next, as illustrated in FIGS. 5A to 5C, the SiGe layers 4 and 5 as high-density Ge layers containing Ge at 30% or more are selectively eliminated. Although various methods are proposed as the elimination method of the elimination, here, the layers are eliminated by using, for example HCl gas etching, wet etching, or the like.

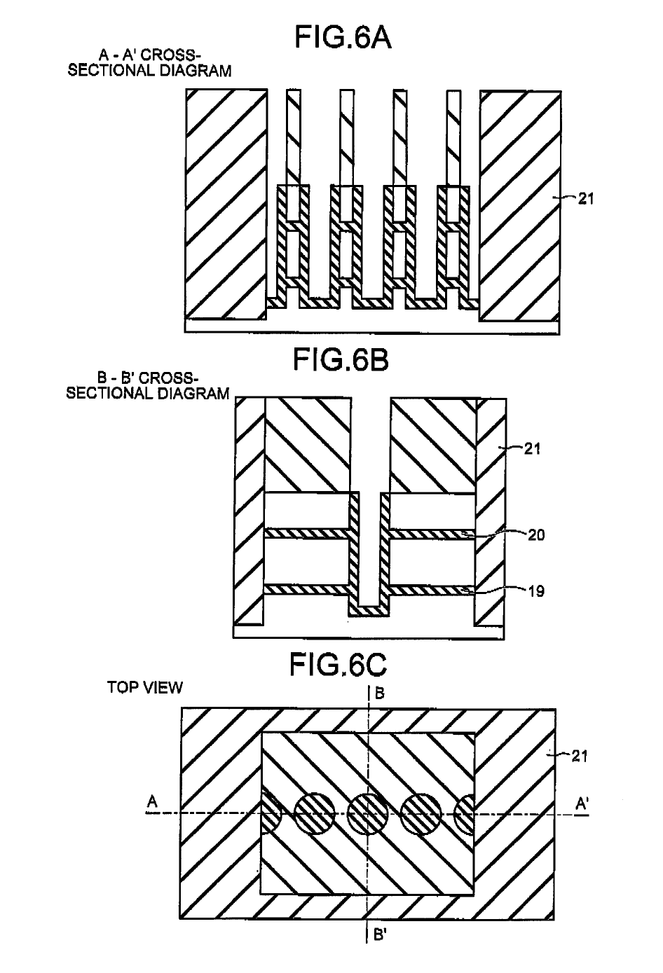

Next, as illustrated in FIGS. 6A to 6C, thermal oxidation is performed, and an area, in which the SiGe layers 4 and 5 having a high density of Ge are formed as films as illustrated in FIGS. 4A to 4C, is converted into SiO₂. A phenomenon is used in which, when Si is thermally oxidized, SiO₂ having a thickness of 1.5 times the film thickness is formed so as to be thicker than the original Si surface by about 0.5 times. In this embodiment, the film thickness of the SiGe layers 4 and 5 containing 30% Ge is 10 nm, and accordingly, by performing thermal oxidation of 15 nm or more, the space between the channels Si of the n-type and the p-type is buried with SiO₂.

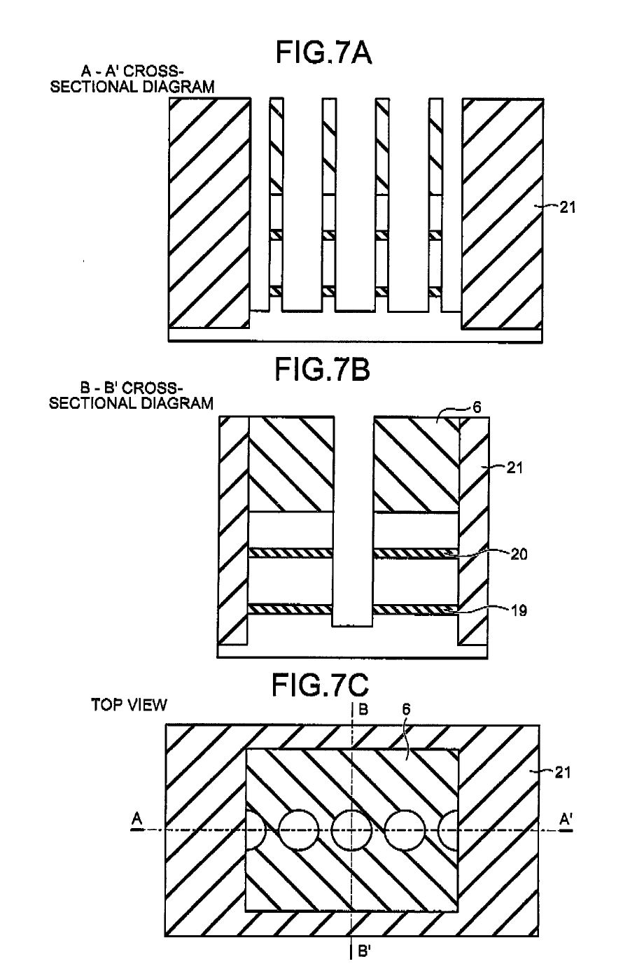

Next, as illustrated in FIGS. 7A to 7C, by etching SiO₂ formed as illustrated in FIGS. 6A to 6C by about 15 nm through isotropic etching such as wet etching, the cross-sections as illustrated in FIGS. 7A and 78 are formed.

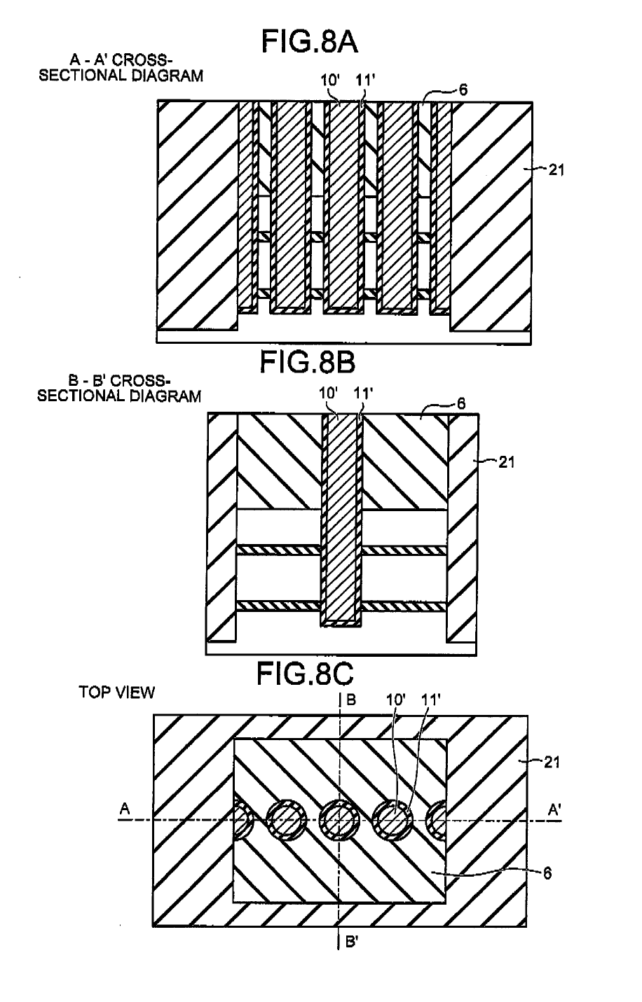

Next, as illustrated in FIGS. 8A to 8C, a gate electrode 10′ is buried in a gate insulating film 11′. Here, after oxynitride is formed through CVD or thermal oxidation as the gate insulating film 11′, a polycrystalline Si is buried as the gate electrode 10′ through CVD.

In the present invention, in order to form the gate electrode 10′ as a damascene gate that is acquired by eliminating the gate electrode once later and burying a metal gate electrode again, here a dummy gate electrode 10′ is formed. It is preferable that a polycrystalline Si is formed over the entire surface as a film, and then is planarized by using CMP technology for burying the gate electrode 10′.

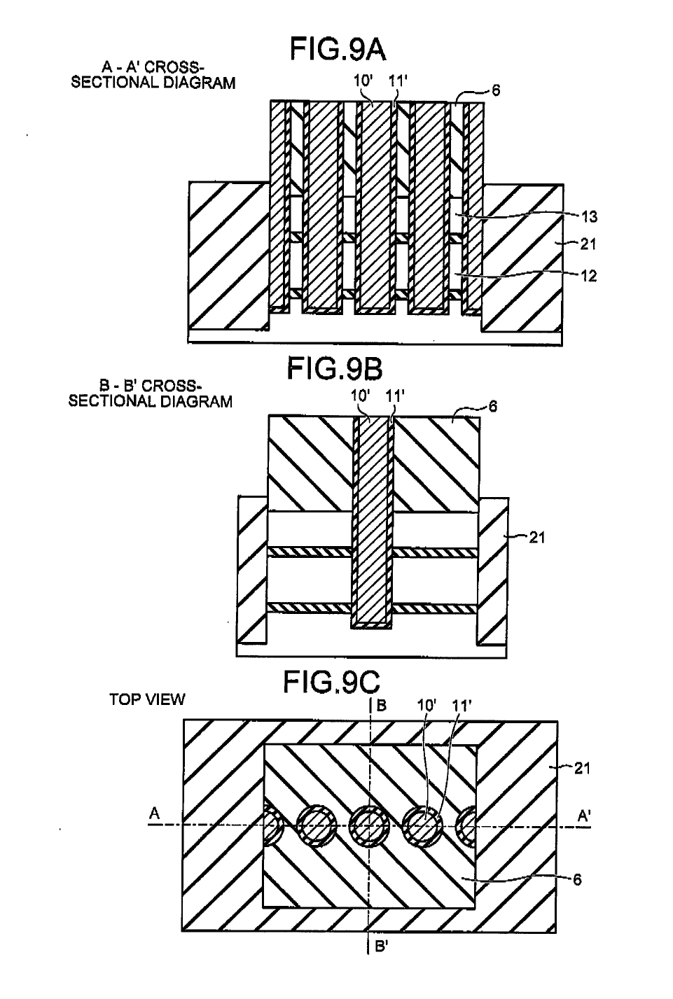

Next, as illustrated in FIGS. 9A and 9C, in order to decrease the height of an STI oxidation film 21, the STI oxidation film 21 is etched up to about the surface of the channel 13 of the n-type FET by using wet technology or the like (FIGS. 9A and 9B). The reason for this is that the side wall is not formed in an unnecessary area in a side-wall forming process to be performed later.

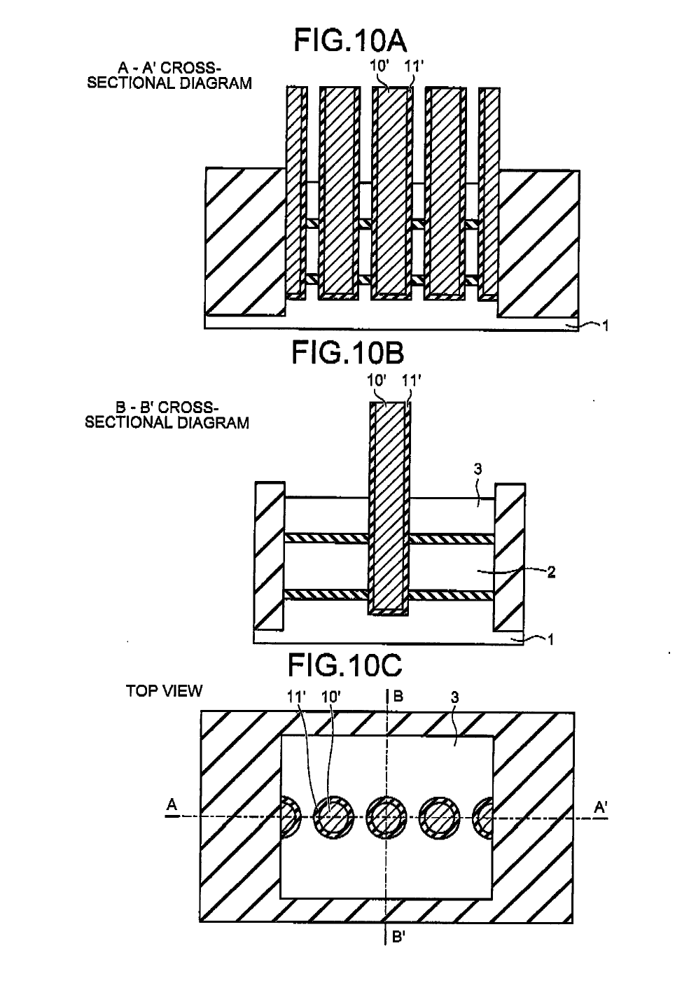

Next, as illustrated in FIGS. 10A to 10C, the SiN film 6 that is used as the hard mask for processing is eliminated using hot phosphoric acid or the like.

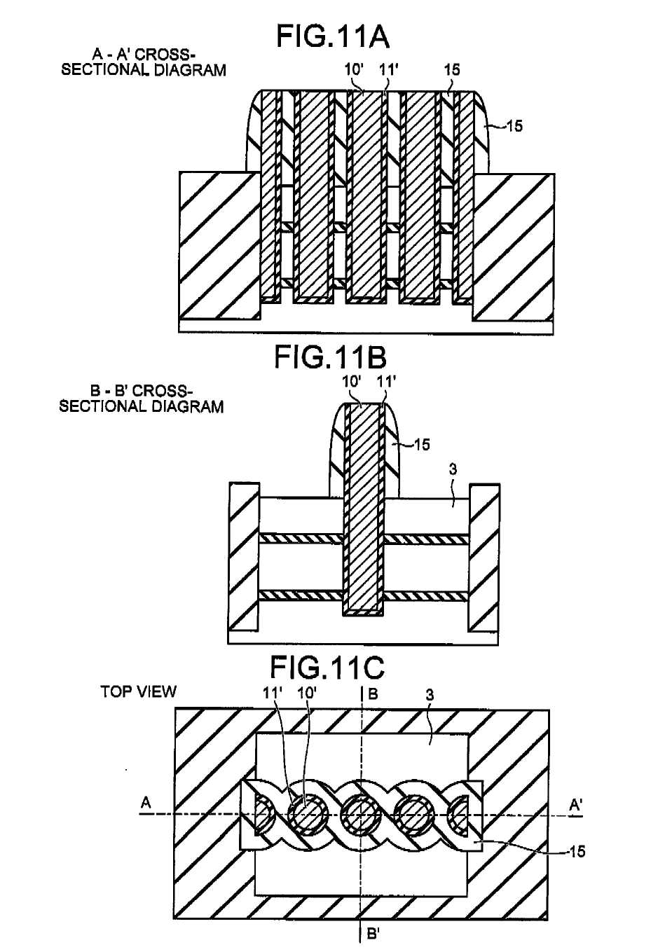

Next, as illustrated in FIGS. 11A to 11C, the side-wall insulating film 15 of the gate electrode 10′, for example, is formed with SiN. At this time, the thickness of the side-wall insulating film 15 needs to be sufficient to fill or excessively cover the space between the gate electrode 10′ and the gate electrode 10′.

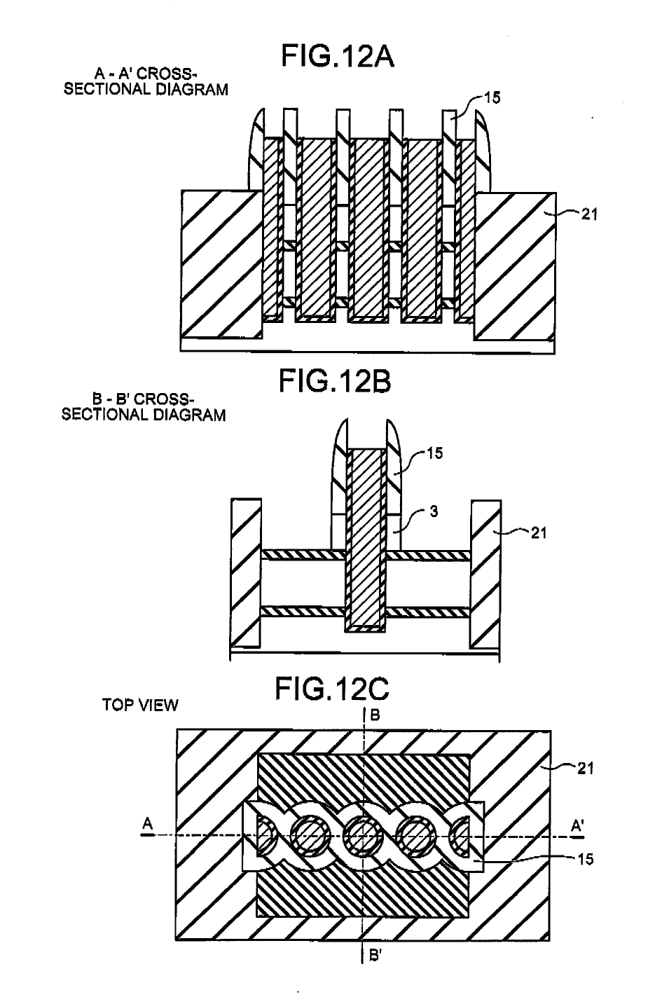

Next, as illustrated in FIGS. 12A to 12C, RIE (etching back) is performed to etch the Si layer 3 of the n-type channel with use of the formed side-wall insulating film 15 as a mask. At this time, the polycrystalline Si of the dummy gate electrode 10′ is also etched.

Next, as illustrated in FIGS. 13A to 13C, by slightly etching SiN of the gate side-wall insulating film 15 with hot phosphoric acid, the side wall of the area in which the gate electrode 10′ is eliminated is eliminated.

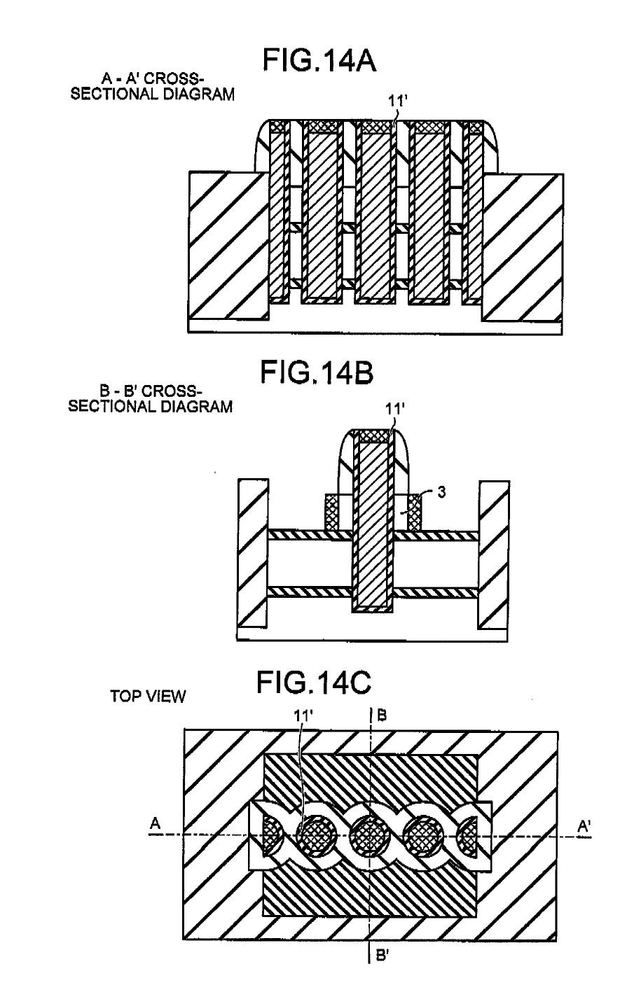

Next; as illustrated in FIGS. 14A to 14C, the side wall of the Si layer 3 that becomes the n-type FET is doped with n-type impurities such as arsenic by using plasma impurity doping technology or the like.

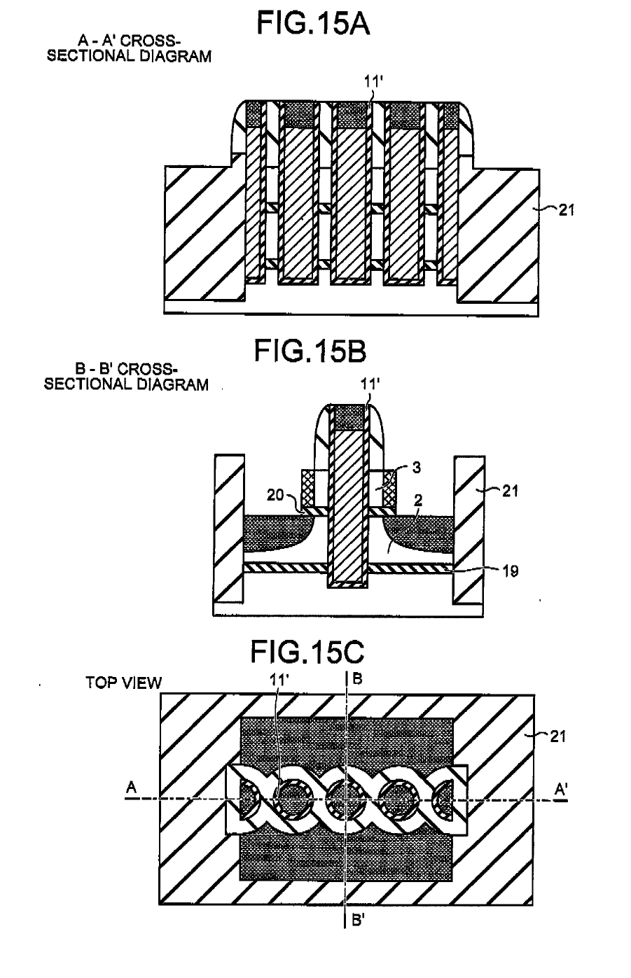

Next, as illustrated in FIGS. 15A to 15C, the RIE is performed to etch the SiO₂ film 20 separating the Si layer 3 that becomes the n-type FET and the SiGe (or Si) layer 2 that becomes the p-type FET from each other, and the SiGe (or Si) layer 2 that becomes the p-type FET is doped with a p-type impurity such as boron through ion implantation (I/I).

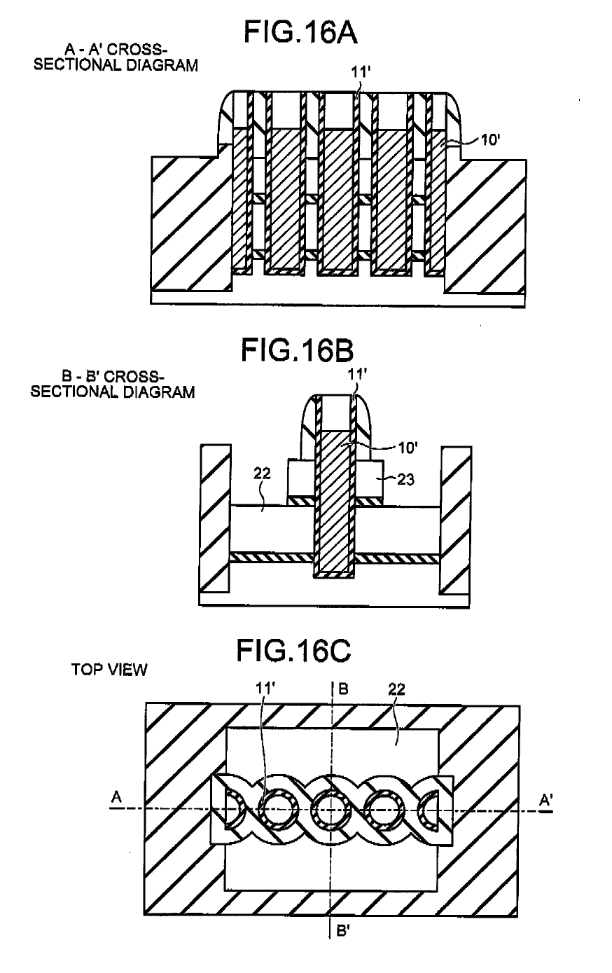

Next, as illustrated in FIGS. 16A to 16C, by performing an impurity activating heat treatment, the n-type source/drain layer 23 and the p-type source/drain layer 22 are formed.

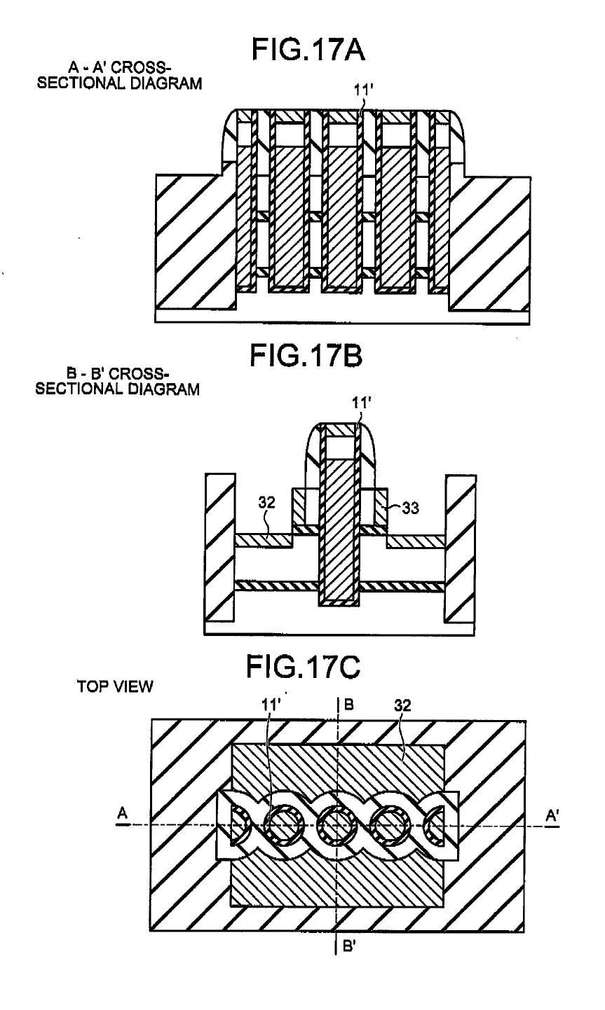

Next, as illustrated in FIGS. 17A to 17C, for example, NiSi (silicide) is formed on the side face of the n-type source/drain layer 23 and the top face of the p-type source/drain layer 22 by using general self-align silicide (salicide) technology using CVD of metal such as Ni. Accordingly, an n-type FET S/D silicide layer 33 is formed on the side face of the n-type source/drain layer 23, and a p-type FET S/D silicide layer 32 is formed on the top face of the p-type source/drain layer 22.

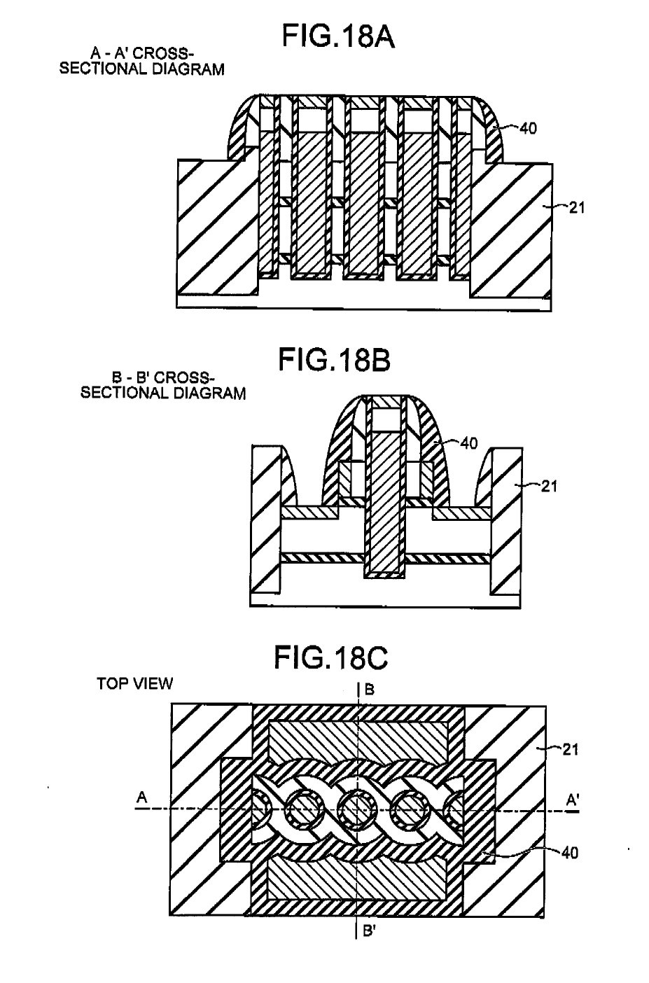

Next, as illustrated in FIGS. 18A to 18C, a SiO₂ film 40 that becomes the stopper of contact electrode processing of the n-type MOSFET source/drain later is formed as a film.

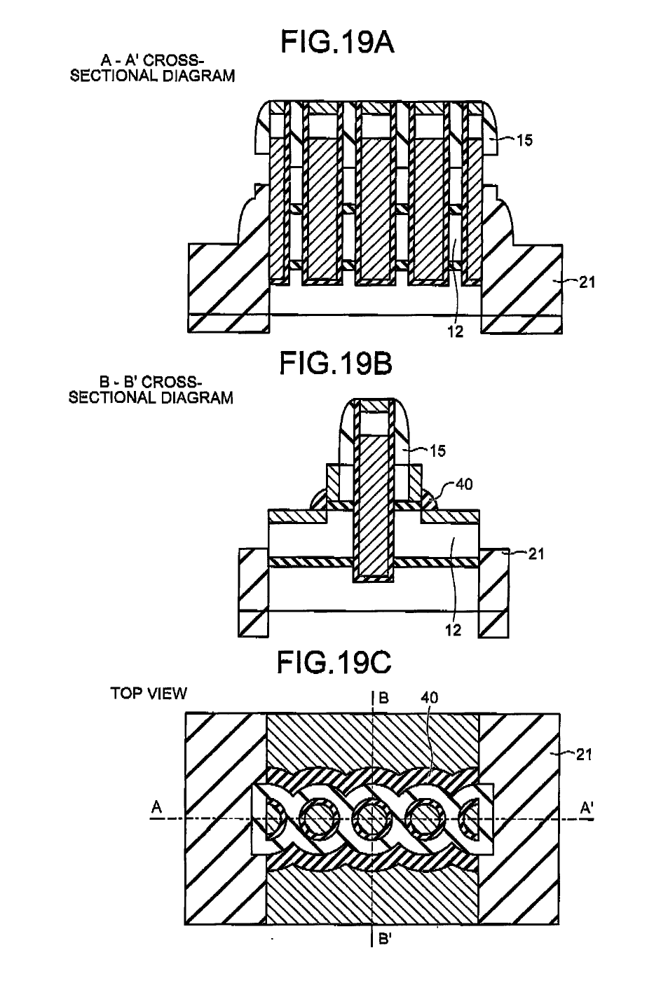

Next, as illustrated in FIGS. 19A to 19C, by processing the side wall of the SiO₂ film 40 that becomes the stopper, a side wall 40 that becomes the stopper for processing of the contact electrodes of the n-type MOSFET source/drain is formed. When this side wall is processed, the STI layer 21 is simultaneously etched such that the STI layer 21 has a height of about the height of the top face of the channel of the p-type MOSFET.

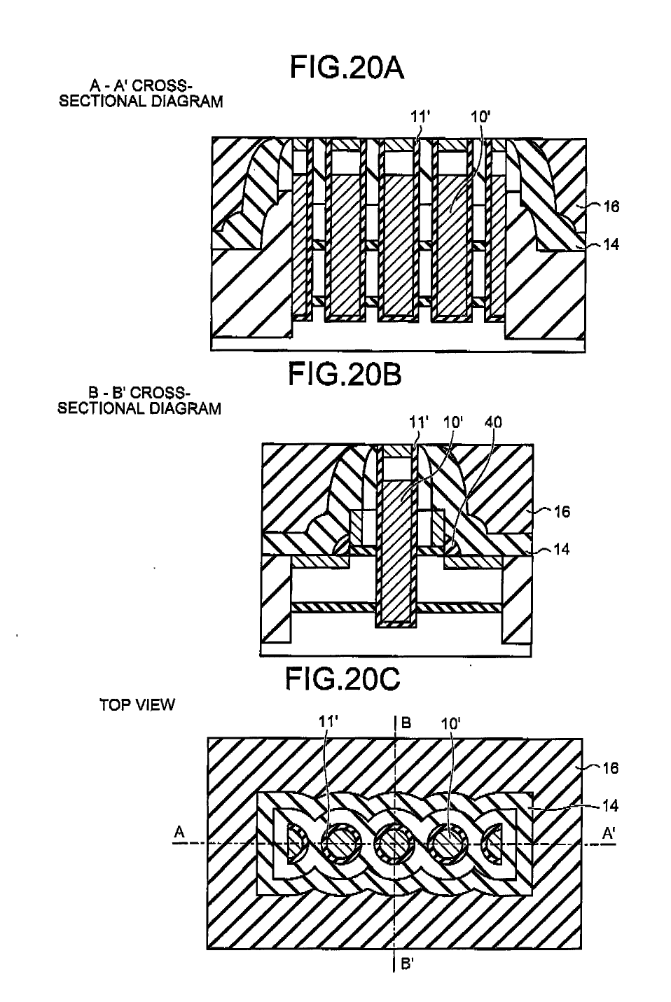

Next, as illustrated in FIGS. 20A to 20C, a barrier SiN film 14 is formed as a film that is used to improve the mobility of the channel by applying stress to a contact processing stopper 40 and the n-type MOSFET. Subsequently, an interlayer SiO₂ film 16 is formed as a film, and planarization is further performed so as to expose the top face of the gate.

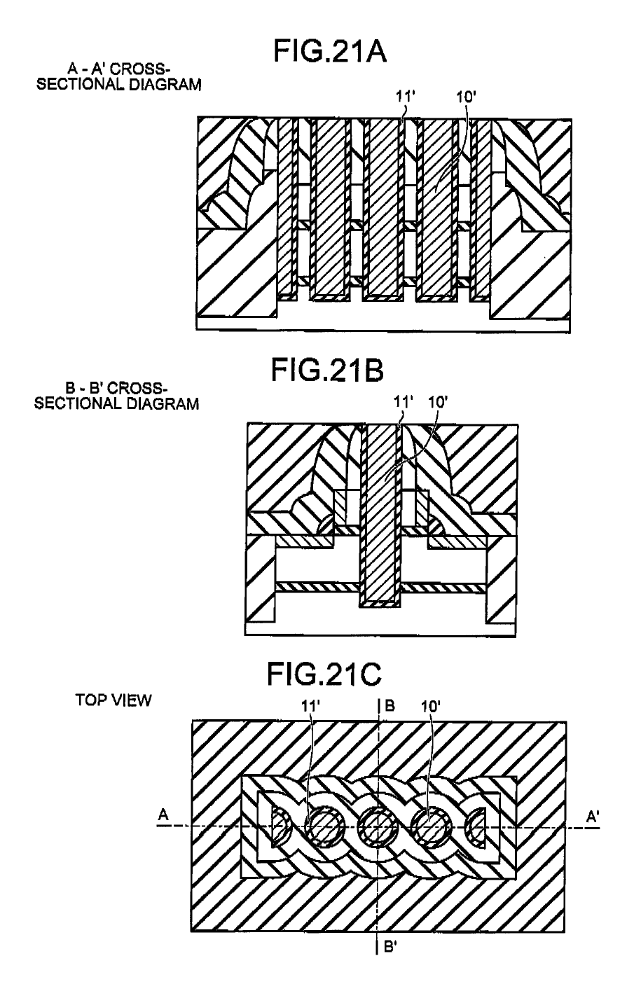

Next, as illustrated in FIGS. 21A to 21C, the polycrystalline Si that is the dummy gate electrode 10′ and the dummy gate insulating film 11′ are eliminated by using damascene gate technology, and a metal gate electrode 10 is buried as the gate insulating film 11. For example, TiN is buried as the metal gate electrode 10. Alternatively, the metal gate electrode 10 may be formed by completely converting the crystalline Si gate electrode 10′, which is formed in advance, into NiSi by using salicide technology (conversion of the gate electrode 10′ into Ni·FUSI).

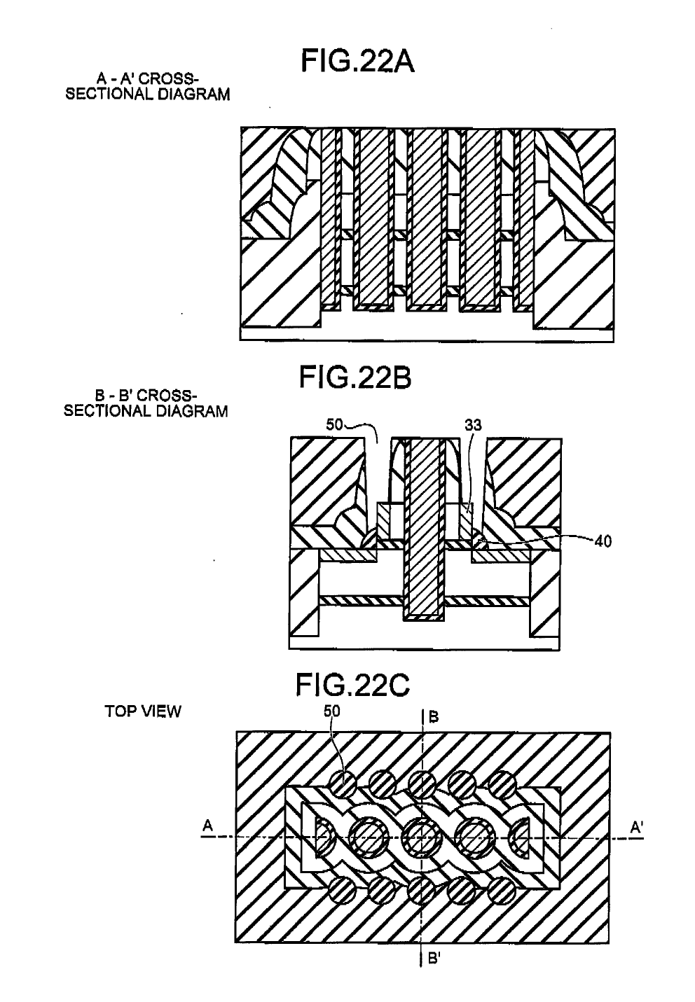

Next, as illustrated in FIGS. 22A to 22C, the RIE is performed so as to process a hole 50 that becomes a source/drain contact of the n-type MISFET (FIG. 22B). The processing is stopped at the side-wall oxidation film 40 that is used as a contact stopper, and accordingly, the hole passes through up to the n-type FET S/D silicide layer 33 without being brought into contact with the p-type FET region.

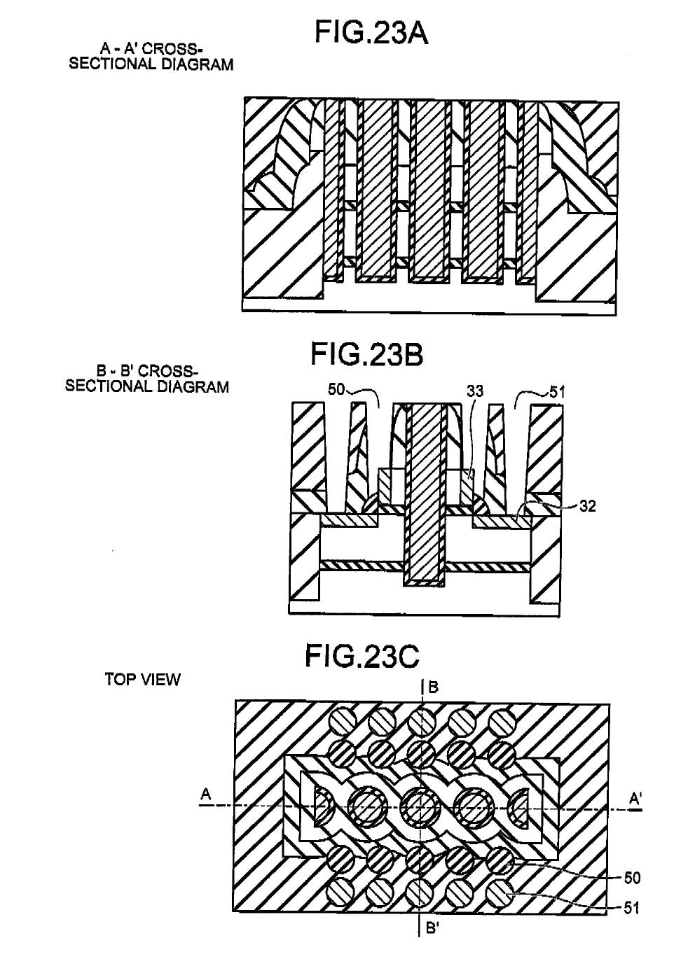

Next, as illustrated in FIGS. 23A to 23C, the RIE is performed so as to process a hole 51 that becomes the source/drain contact of the p-type MISFET, and accordingly, the hole passes through up to the p-type FET S/D silicide layer 32 (FIG. 238).

Finally, the n-type FET contact 17 and the p-type FET contact 18 are formed by burying metals such as Ti and W that form the contact electrodes in the holes 50 and 51 of the contacts illustrated in FIGS. 23A to 23C. Accordingly, a semiconductor device 100 having the MISFET structure according to this embodiment illustrated in FIGS. 1A to 1C is formed.

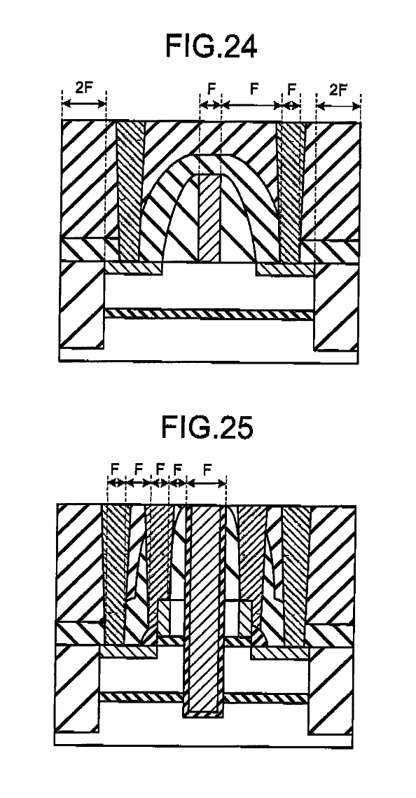

The CMOS design rules according to the conventional technology and this embodiment will be compared with each other assuming that the limit distance of lithography is a half pitch (HP)=F, in other words, line/space=F/F (a total of 2F). While the n-type single MOSFET and the p-type single MOSFET that constitute a conventional CMOS have designed sizes as illustrated in FIG. 24, the n-type/p-type MOSFET stacked structure according to this embodiment has designed sizes as illustrated in FIG. 25.

In other words, in the conventional CMOS design rule, although a distance of 2F is necessary between an n well of the n-type MOSFET and a p well of the p-type MOSFET even in the worst case, as illustrated in FIG. 24, in the case of this embodiment, the n-type/p-type stacked structure is employed, and accordingly, a distance between the wells is not necessary, thereby the degree of integration is improved.

The aspects of the semiconductor device and the method of manufacturing thereof according to this embodiment described as above are as below.

First, the stacked structure of the n-type/p-type MOSFETs is formed. In addition, a MOSFET having an FINFET structure, which is advantageous in operations performed in response to the miniaturization of the gate length, can be stacked. In other words, there is an advantage in that the amount of the current can be increased by increasing the width of the MOSFET layer in the extension direction (a depth direction) of the columnar gate electrodes while maintaining the degree of two-dimensional integration.

Then, the gate wiring of each of the n-type MOSFET and the p-type MOSFET has a structure that is connected in advance. Accordingly, there is no need to newly connect gate wirings of the n-type MOSFET and the p-type MOSFET so as to configure an inverter. In other words, the semiconductor device 100 according to this embodiment is a basic constituent element of an inverter element.

In addition, differently from the conventional technology, the n-type MOSFET and the p-type MOSFET can be formed by performing the photolithographic process once to form an element region and the gate electrodes. Accordingly, the number of the photolithographic processes can be less than that of a conventional CMOS process.

In addition, in this embodiment, although a case has been described in which the conductivity type of the channel layer 12 that is the first semiconductor layer located in the lower layer illustrated in FIGS. 1A to 1C is the p-type, and the conductivity type of the channel layer 13 that is the second semiconductor layer located in the upper layer is the n-type, even in a case where the conductivity types are reversed in the channel layers, the same advantages described above can be acquired.

### Second Embodiment

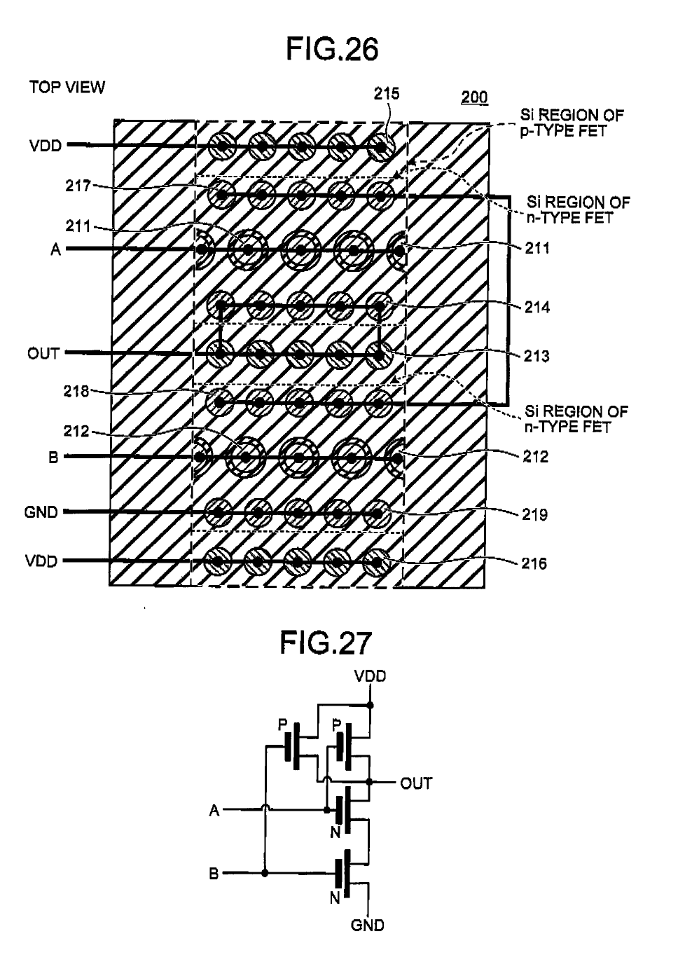

FIG. 26 is a top view illustrating a semiconductor device 200 constituting a NAND circuit according to a second embodiment of the invention. The semiconductor device 200 includes two semiconductor devices 100 according to the first embodiment illustrated in FIGS. 1A to 1C, each forming a basic configuration of an inverter element, such that a row (first group) of columnar gate electrodes 211 and a row (second group) of gate electrodes 212, for example, are aligned so as to be parallel to each other as illustrated in FIG. 26.

Accordingly, in the lower layer and the upper layer in the downward direction perpendicular to the sheet surface of the top view illustrated in FIG. 26, a p-type (the first conductivity type) first MOSFET and an n-type (the second conductivity type) second MOSFET that use common gate electrodes 211 are formed so as to be stacked. Similarly, in the lower layer and the upper layer in the downward direction perpendicular to the sheet surface, a p-type third MOSFET and an n-type fourth MOSFET that use common gate electrodes 212 are formed so as to be stacked.

The semiconductor device 200 having the above-described structure illustrated in FIG. 26 can be formed by using the same manufacturing method as in the first embodiment. Accordingly, the p-type channel layers of the first and third MOSFETs can be simultaneously formed, and the n-type channel layers of the second and fourth MOSFETs can be simultaneously formed.

The semiconductor device 200 configures the NAND circuit that is illustrated in the circuit diagram shown in FIG. 27. Described in more detail, as illustrated in FIG. 26, adjacent columnar gate electrodes 211 of the first group are connected to a first input terminal A of the NAND circuit, and adjacent columnar gate electrodes 212 of the second group are connected to a second input terminal B of the NAND circuit.

In addition, both a contact 213 that is connected to one diffusion layer of the first MOSFET and a contact 214 that is connected to one diffusion layer of the second MOSFET are connected to an output terminal OUT, both a contact 215 that is connected to the other diffusion layer of the first MOSFET and a contact 216 that is connected to one diffusion layer of the third MOSFET are connected to VDD, a contact 217 that is connected to the other diffusion layer of the second MOSFET and a contact 218 that is connected to one diffusion layer of the fourth MOSFET are connected together, the other diffusion layer of the third MOSFET is connected to the output terminal OUT through the contact 213, and a contact 219 that is connected to the other diffusion layer of the fourth MOSFET is connected to GND, whereby a NAND circuit is formed.

In addition, in the description presented above, although a case has been described in which the conductivity type of the first and third MOSFETs, which are formed in the lower layer, is the p-type, and the conductivity type of the second and fourth MOSFETs, which are formed in the upper layer is the n-type, even in a case where the conductivity types are reversed in the upper and lower layers, in other words, even in a case where the first and third MOSFETs are the n-type, and the second and fourth MOSFETs are the p-type, a NAND circuit can be configured.

In other words, adjacent columnar gate electrodes of the first group are connected to a first input terminal A of the NAND circuit, adjacent columnar gate electrodes of the second group are connected to a second input terminal B of the NAND circuit, both one diffusion layer of the first MOSFET and one diffusion layer of the second MOSFET are connected to an output terminal OUT, the other diffusion layer of the first MOSFET and one diffusion layer of the third MOSFET are connected together, both the other diffusion layer of the second MOSFET and one diffusion layer of the fourth MOSFET are connected to VDD, the other diffusion layer of the fourth MOSFET is connected to the output terminal OUT, and the other diffusion layer of the third MOSFET is connected to GND, whereby a NAND circuit can be configured (not shown in the figure).

The above-described semiconductor device according to this embodiment can form a NAND circuit that has a degree of integration higher than that of a conventional device and a photolithographic cost lower than a conventional device based on the same reasons as those of the first embodiment.

### Third Embodiment

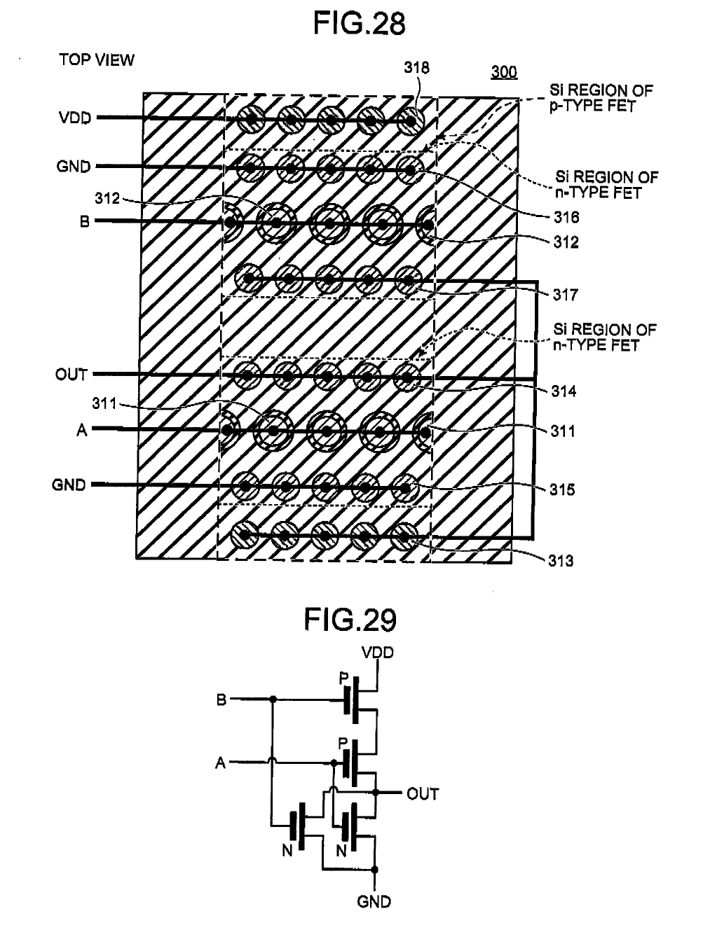

FIG. 28 is a top view illustrating a semiconductor device 300 configuring a NOR circuit according to a third embodiment of the invention. The semiconductor device 300 includes two semiconductor devices 100 according to the first embodiment illustrated in FIGS. 1A to 1C, each forming a basic configuration of an inverter element, such that a row (first group) of columnar gate electrodes 311 and a row (second group) of gate electrodes 312, for example, are aligned so as to be parallel to each other as illustrated in FIG. 28.

Accordingly, in the lower layer and the upper layer in the downward direction perpendicular to the sheet surface of the top view illustrated in FIG. 28, a p-type (the first conductivity type) first MOSFET and an n-type (the second conductivity type) second MOSFET that use common gate electrodes 311 are formed so as to be stacked. Similarly, in the lower layer and the upper layer in the downward direction perpendicular to the sheet surface, a p-type third MOSFET and an n-type fourth MOSFET that use common gate electrodes 312 are formed so as to be stacked.

The semiconductor device 300 having the above-described structure illustrated in FIG. 28 can be formed by using the same manufacturing method as that described in the first embodiment. Accordingly, the p-type channel layers of the first and third MOSFETs can be simultaneously formed, and the n-type channel layers of the second and fourth MOSFETs can be simultaneously formed.

The semiconductor device 300 configures the NOR circuit that is illustrated in the circuit diagram shown in FIG. 29. Described in more detail, as illustrated in FIG. 28, adjacent columnar gate electrodes 311 of the first group are connected to a first input terminal A of the NOR circuit, and adjacent columnar gate electrodes 312 of the second group are connected to a second input terminal B of the NOR circuit.

In addition, both a contact 313 that is connected to one diffusion layer of the first MOSFET and a contact 314 that is connected to one diffusion layer of the second MOSFET are connected to an output terminal OUT, the other diffusion layer of the first MOSFET and one diffusion layer of the third MOSFET are connected in the downward side of the sheet surface (not shown in the figure), both a contact 315 that is connected to the other diffusion layer of the second MOSFET and a contact 316 that is connected to one diffusion layer of the fourth MOSFET are connected to GND, a contact 317 that is connected to the other diffusion layer of the fourth MOSFET is connected to the output terminal OUT through a contact 317, and a contact 318 that is connected to the other diffusion layer of the third MOSFET is connected to VDD, whereby a NOR circuit is formed.

In addition, in the-description presented above, although a case has been described in which the conductivity type of the first and third MOSFETs, which are formed in the lower layer, is the p-type, and the conductivity type of the second and fourth MOSFETs, which are formed in the upper layer is the n-type, even in a case where the conductivity types are reversed in the upper and lower layers, in other words, even in a case where the first and third MOSFETs are the n-type, and the second and fourth MOSFETs are the p-type, a NOR circuit can be configured.

In other words, adjacent columnar gate electrodes of the first group are connected to a first input terminal A of the NOR circuit, adjacent columnar gate electrodes of the second group are connected to a second input terminal B of the NOR circuit, both one diffusion layer of the first MOSFET and one diffusion layer of the second MOSFET are connected to an output terminal OUT, both the other diffusion layer of the first MOSFET and one diffusion layer of the third MOSFET are connected to GND, the other diffusion layer of the second MOSFET and one diffusion layer of the fourth MOSFET are connected together, the other diffusion layer of the third MOSFET is connected to the output terminal OUT, and the other diffusion layer of the fourth MOSFET is connected to VDD, whereby a NOR circuit can be configured (not shown in the figure).

The above-described semiconductor device according to this embodiment can form a NOR circuit that has a degree of integration higher than that of a conventional device and a photolithographic cost lower than a conventional device based on the same reasons as those of the first embodiment.

### Fourth Embodiment

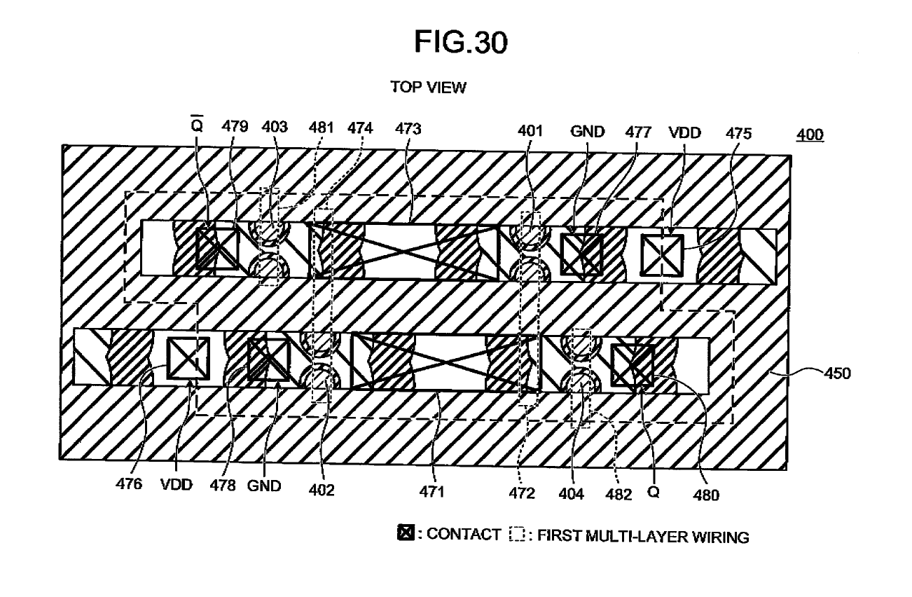

FIG. 30 is a top view illustrating a semiconductor device 400 configuring an SRAM cell circuit of six transistors according to a fourth embodiment of the invention. The semiconductor device 400 includes four semiconductor devices 100 according to the first embodiment illustrated in FIGS. 1A to 1C, each forming a basic configuration of an inverter element.

In the semiconductor device 400, a row (first group) of columnar gate electrodes 401, a row (second group) of columnar gate electrodes 402, a row (third group) of columnar gate electrodes 403, a row (fourth group) of columnar gate electrodes 404 corresponding to four semiconductor devices 100 are configured, for example, so as to be aligned parallel to one other as illustrated in FIG. 30. However, the row (the first group) of the gate electrodes 401 and the row (the fourth group) of the gate electrodes 404 are aligned so as to be deviated from each other, and the row (the second group) of the gate electrodes 402 and the row (the third group) of the gate electrodes 403 are aligned so as to be deviated from each other.

In other words, in FIG. 30, a rectangular structure including the gate electrodes 401 and 403 and a rectangular structure including the gate electrodes 402 and 404, which are separated by an STI region 450, are horizontally deviated from each other. This one rectangular structure is a structure in which two semiconductor devices 100 illustrated in FIGS. 1A to 1C are aligned so as to have the rows of the gate electrodes to be parallel to each other.

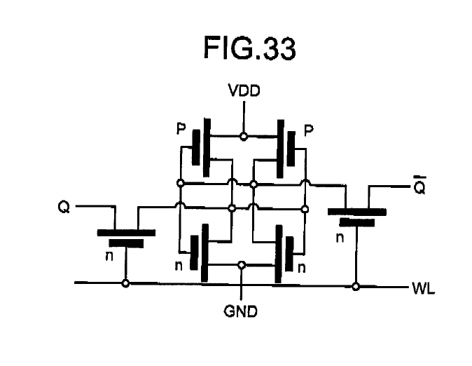

However, in each of the row (the third group) of the gate electrodes 403 and the row (the fourth group) of the gate electrodes 404, an n-type MOSFET may be formed in the downward direction perpendicular to the sheet surface of FIG. 30, and a p-type MOSFET may not be necessarily formed. The reason for this is that the SRAM cell circuit of six transistors illustrated in the circuit diagram of FIG. 33, which is configured by the semiconductor device 400, is configured by four n-type MOSFETs and two p-type MOSFETs.

Accordingly, in the lower layer and the upper layer in the downward direction perpendicular to the sheet surface of the top view illustrated in FIG. 30, a p-type (the first conductivity type) first MOSFET and an n-type (the second conductivity type) second MOSFET that use common gate electrodes 401 are formed so'as to be stacked. Similarly, in the lower layer and the upper layer in the downward direction perpendicular to the sheet surface, a p-type third MOSFET and an n-type fourth MOSFET that use common gate electrodes 402 are formed so as to be stacked. In addition, in the same layer of that of the second and fourth MOSFETs in the downward direction perpendicular to the sheet surface, n-type fifth and sixth MOSFETs that use common gate electrodes 403 and 404 are formed.

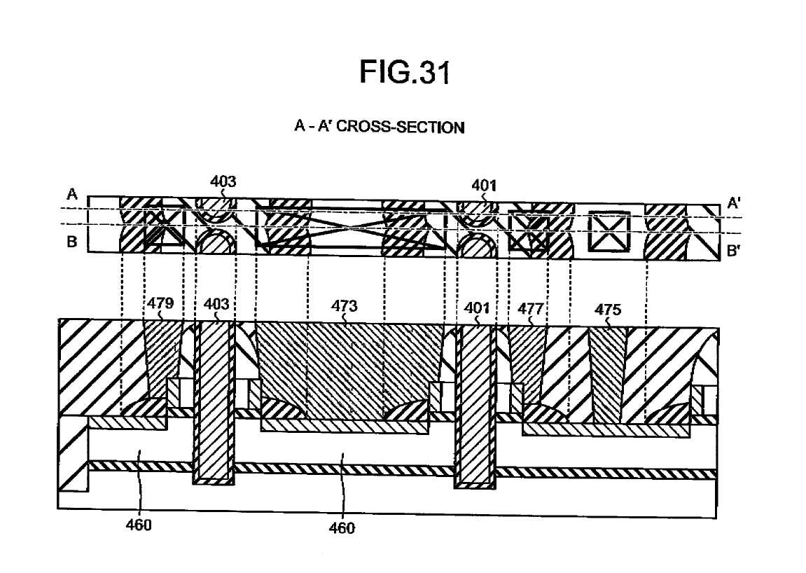

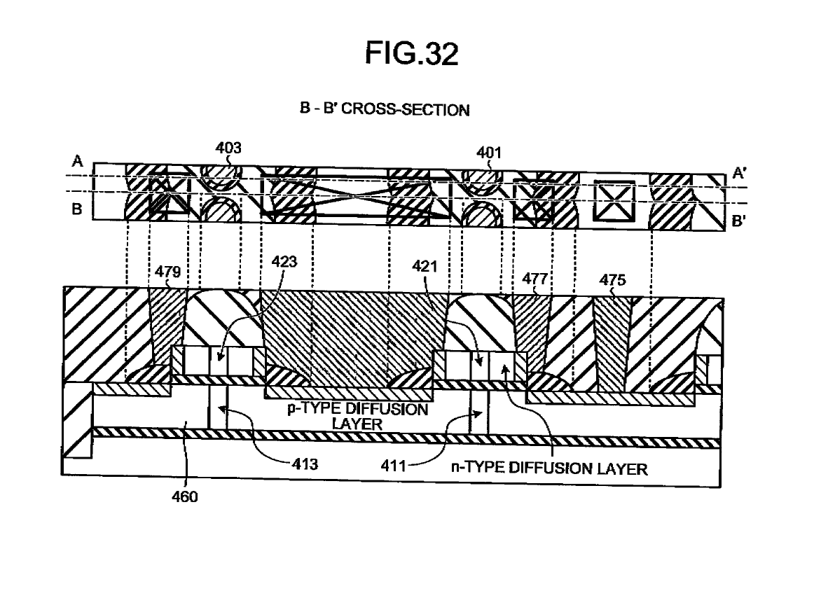

FIGS. 31 and 32 are cross-sectional views of the rectangular structure including the gate electrodes 401 and 403 illustrated in FIG. 30 in the direction perpendicular to the sheet surface. FIG. 31 is a cross-sectional view, which is taken along line A-A′, of the face cutting the gate electrodes 401 and 403, and FIG. 32 is a cross-sectional view, which is taken along line B-B′, of the face cutting the p-type channel layers 411 and 413 and the n-type channel layers 421 and 423. As can be understood from both the figures, in one p-type diffusion layer 460 (the left side of the gate electrode 403 illustrated in FIG. 31) through which the gate electrode 403 passes, there is no contact, and accordingly, a p-type MOSFET is not formed therein.

The semiconductor device 400 having the above-described structure illustrated in FIG. 30 can be formed by using the same manufacturing method as that described in the first embodiment. Accordingly, the p-type channel layers of the first and third MOSFETs can be simultaneously formed, and the n-type channel layers of the second, fourth, fifth, and sixth MOSFETs can be simultaneously formed.

The semiconductor device 400 configures the SRAM cell circuit of six transistors that is illustrated in the circuit diagram shown in FIG. 33. Described in more detail, one diffusion layer of the third MOSFET, one diffusion layer of the fourth MOSFET, and one diffusion layer of the sixth MOSFET are connected together through a contact 471 illustrated in FIG. 30. The contact 471 is connected to the columnar gate electrode 401 of the first group through a first multi-layer wiring 472 denoted by a broken line in FIG. 30.

In addition, one diffusion layer of the first MOSFET, one diffusion layer of the second MOSFET, and one diffusion layer of the fifth MOSFET are connected together through a contact 473 illustrated in FIGS. 30 to 32. The contact 473 is connected to the columnar gate electrode 402 of the second group through a first multi-layer wiring 474 denoted by a broken line in FIG. 30. Actually, the first multi-layer wirings 472 and 474 are placed in the direction perpendicular to the sheet surface relative to the layers illustrated in FIG. 30.

In addition, the other diffusion layer of the first MOSFET is connected to VDD through a contact 475 illustrated in FIGS. 30 to 32, and the other diffusion layer of the third MOSFET is connected to VDD through a contact 476 illustrated in FIG. 30. Furthermore, the other diffusion layer of the second MOSFET is connected to GND through a contact 477 illustrated in FIGS. 30 to 32, and the other diffusion layer of the fourth MOSFET is connected to GND through a contact 478 illustrated in FIG. 30.

Furthermore, the other diffusion layer of the fifth MOSFET is connected to a “ attached Q” terminal through a contact 479 illustrated in FIGS. 30 to 32, and the other diffusion layer of the sixth MOSFET is connected to a “Q” terminal through a contact 480 illustrated in FIG. 30.

Then, the columnar gate electrodes 403 of the third group and a first multi-layer wiring 481 denoted by a broken line illustrated in FIG. 30 are connected together, the columnar gate electrodes 404 of the fourth group and a first multi-layer wiring 482 denoted by a broken line illustrated in FIG. 30 are connected together, and both the first multi-layer wirings 481 and 482 are connected to a word line (WL), whereby the SRAM cell circuit illustrated in FIG. 33 is configured.

In addition, as described above, the actual first multiple-layer wirings 481 and 482 are placed in the direction perpendicular to the sheet surface relative to the layer illustrated in FIG. 30. In addition, it may be configured that a plurality of the SRAM cell structures illustrated in FIG. 30 is periodically formed in the two-dimensional direction of the sheet surface, and the first multiple-layer wirings 481 and 482 are connected to the columnar gate electrodes of different n-type MOSFETs.

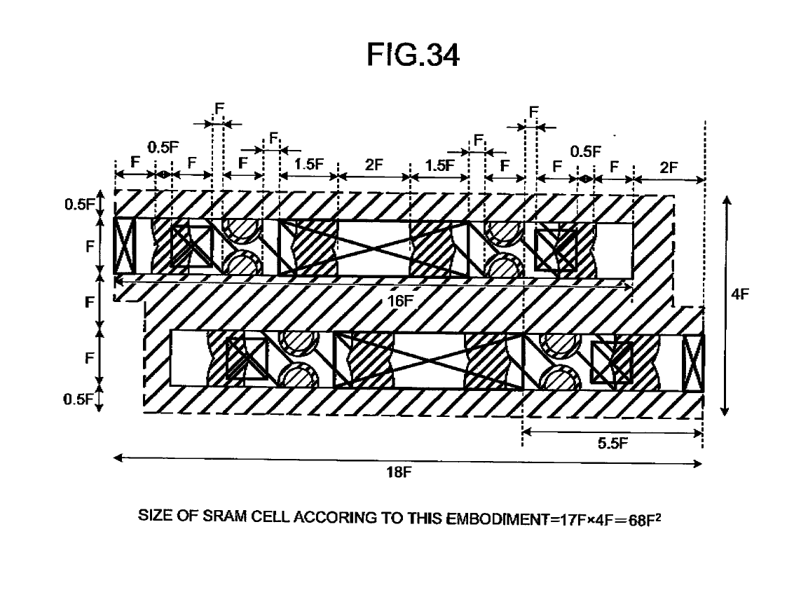

In the example of the SRAM cell structure according to this embodiment illustrated in FIG. 30, the designed sizes of estimated circuit areas are shown in FIG. 34 assuming that the limit distance of lithography is a half pitch (HP)=F, in other words, line/space=F/F (a total of 2F). Although The minimum unit area of the cell in the case where the line and space are a total of 2F is 4·F2, the size of the SRAM cello according to this embodiment is 68·F2 as illustrated in FIG. 34, and accordingly, the occupied areas of components can be smaller than that of a conventional MOSFET circuit that is not stacked.

In addition, in the description presented above, although a case has been described in which the conductivity type of first and third MOSFETs formed in the lower layer is the p-type, and the conductivity type of the second, fourth, fifth, and sixth MOSFETs is the n-type, even in a case where the conductivity types are reversed in the upper and lower layers, in other words, even in a case where the first, third, fifth, and sixth MOSFETs formed in the lower layer are n-type MOSFETs, and the second and fourth MOSFETs formed in the upper layer are p-type MOSFETs, an SRAM cell circuit can be configured. In such a case, although the fifth and sixth MOSFETs are formed in the lower layer, the fifth and sixth MOSFETs are the n-type MOSFETs without any change.

In other words, adjacent columnar gate electrodes of the first group, one diffusion layer of the third MOSFET, one diffusion layer of the fourth MOSFET, and one diffusion layer of the sixth MOSFET are connected together, adjacent columnar gate electrodes of the second group, one diffusion layer of the first MOSFET, one diffusion layer of the second MOSFET, and one diffusion layer of the fifth MOSFET are connected together, both the other diffusion layer of the first MOSFET and the other diffusion layer of the third MOSFET are connected to GND, both the other diffusion layer of the second MOSFET and the other diffusion layer of the fourth MOSFET are connected to VDD, the other diffusion layer of the fifth MOSFET is connected to the “ attached Q” terminal, the other diffusion layer of the sixth MOSFET is connected to the “Q” terminal, and all adjacent columnar gate electrodes of the third group and adjacent columnar gate electrodes of the fourth group are connected to a WL, whereby a SRAM cell circuit can be configured (not shown in the figure).

The above-described semiconductor device according to this embodiment can form a SRAM cell circuit that has a degree of integration higher than that of a conventional device and a photolithographic cost lower than a conventional device based on the same reasons as those of the first embodiment.

According to the semiconductor device according to the above-described embodiment and the method of manufacturing thereof, n-type and p-type MISFETS (MOSFETs) can be stacked so as to realize improvement in the degree of integration of circuits by performing photolithography of each of the element region and the gate electrode once.

To be described in more detail, after an element region in which the n-type and the p-type are stacked is processed, a gate electrode, for example, having a cylindrical shape is formed by passing the gate electrode through the element region. Accordingly, a FiNFET structure for performing a double gate operation can be formed in the stacked structure. In the above-described embodiment, since the gate electrodes of the n-type and p-type FETs are connected in advance when the MOSFETs are formed, it is possible to form an inverter circuit simultaneously with the formation of the MOSFETs. Therefore, it is possible to form a NAND circuit, a NOR circuit, an SRAM cell circuit of six transistors, and the like having a high degree of integration.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a plurality of columnar gate electrodes of a first group that are formed so as to be separated from one another in a row on a semiconductor substrate;
a first gate insulating film that covers side surfaces of the columnar gate electrodes of the first group;
a first semiconductor layer of a first conductivity type that is formed on the semiconductor substrate, between the columnar gate electrodes of the first group that are adjacent to each other;
a first insulating layer that is formed on the first semiconductor layer between the adjacent columnar gate electrodes of the first group; and
a second semiconductor layer of a second conductivity type different from the first conductivity type, which is formed on the first insulating layer, between the adjacent columnar gate electrodes of the first group;
wherein a first MOSFET of the first conductivity type that uses the first semiconductor layer as a channel is formed, and
wherein a second MOSFET of the second conductivity type that uses the second semiconductor layer as a channel is formed.

2. The semiconductor device according to claim 1,
wherein, of widths of the first semiconductor layer and the second semiconductor layer in a direction of extension of the columnar gate electrodes, the width of the semiconductor layer having a conductivity type of the p-type is larger than that of the semiconductor layer having a conductivity type of the n-type.

3. The semiconductor device according to claim 1, further comprising:
a plurality of columnar gate electrodes of a second group that are formed so as to be separated from one another in a row on the semiconductor substrate;
a second gate insulating film that covers side faces of the plurality of columnar gate electrodes of the second group;
a third semiconductor layer of the first conductivity type that is formed on the semiconductor substrate, between the columnar gate electrodes of the second group that are adjacent to each other;
a second insulating layer that is formed on the third semiconductor layer between the adjacent columnar gate electrodes of the second group; and
a fourth semiconductor layer of the second conductivity type that is formed on the second insulating layer between the adjacent columnar gate electrodes of the second group,
wherein a NAND circuit is configured by:
forming a third MOSFET of the first conductivity type that uses the third semiconductor layer as a channel;
forming a fourth MOSFET of the second conductivity type that uses the fourth semiconductor layer as a channel;
connecting the adjacent columnar gate electrodes of the first group to a first input terminal,
connecting the adjacent columnar gate electrodes of the second group to a second input terminal,
connecting both one diffusion layer of the first MOSFET and one diffusion layer of the second MOSFET to an output terminal,
connecting the other diffusion layer of the first MOSFET and one diffusion layer of the third MOSFET together,
connecting the other diffusion layer of the second MOSFET and one diffusion layer of the fourth MOSFET together, and
connecting the other diffusion layer of one of the third and fourth MOSFETs of which the conductivity type is a p type to the output terminal.

4. The semiconductor device according to claim 1, further comprising:
a plurality of columnar gate electrodes of a second group that are formed so as to be separated from one another in a row on the semiconductor substrate;
a second gate insulating film that covers side faces of the plurality of columnar gate electrodes of the second group;
a third semiconductor layer of the first conductivity type that is formed on the semiconductor substrate between the columnar gate electrodes of the second group that are adjacent to each other;
a second insulating layer that is formed on the third semiconductor layer between the adjacent columnar gate electrodes of the second group; and
a fourth semiconductor layer of the second conductivity type that is formed on the second insulating layer between the adjacent columnar gate electrodes of the second group,
wherein a NOR circuit is configured by:
forming a third MOSFET of the first conductivity type that uses the third semiconductor layer as a channel;
forming a fourth MOSFET of the second conductivity type that uses the fourth semiconductor layer as a channel;
connecting the adjacent columnar gate electrodes of the first group to a first input terminal,
connecting the adjacent columnar gate electrodes of the second group to a second input terminal,
connecting both one diffusion layer of the first MOSFET and one diffusion layer of the second MOSFET to an output terminal,
connecting the other diffusion layer of the first MOSFET and one diffusion layer of the third MOSFET together,
connecting the other diffusion layer of the second MOSFET and one diffusion layer of the fourth MOSFET together, and
connecting the other diffusion layer of one of the third and fourth MOSFETs of which the conductivity type is an n type to the output terminal.

5. The semiconductor device according to claim 1, further comprising:
a plurality of columnar gate electrodes of a second group that are formed so as to be separated from one another in a row on the semiconductor substrate;
a second gate insulating film that covers side faces of the plurality of columnar gate electrodes of the second group;
a third semiconductor layer of the first conductivity type that is formed on the semiconductor substrate between the columnar gate electrodes of the second group that are adjacent to each other;
a second insulating layer that is formed on the third semiconductor layer between the adjacent columnar gate electrodes of the second group;
a fourth semiconductor layer of the second conductivity type that is formed on the second insulating layer between the adjacent columnar gate electrodes of the second group;
a plurality of columnar gate electrodes of a third group that are formed so as to be separated from one another in a row on the semiconductor substrate;
a third gate insulating film that covers side faces of the plurality of columnar gate electrodes of the third group;
a fifth semiconductor layer of the first conductivity type that is formed on the semiconductor substrate between the columnar gate electrodes of the third group that are adjacent to each other;
a third insulating layer that is formed on the fifth semiconductor layer between the adjacent columnar gate electrodes of the third group;
a sixth semiconductor layer of the second conductivity type that is formed on the third insulating layer between the columnar gate electrodes of the third group that are adjacent to each other;
a plurality of columnar gate electrodes of a fourth group that are formed so as to be separated from one another in a row on the semiconductor substrate;
a fourth gate insulating film that covers side faces of the plurality of columnar gate electrodes of the fourth group;
a seventh semiconductor layer of the first conductivity type that is formed on the semiconductor substrate between the columnar gate electrodes of the fourth group that are adjacent to each other;
a fourth insulating layer that is formed on the seventh semiconductor layer between the adjacent columnar gate electrodes of the fourth group; and
an eighth semiconductor layer of the second conductivity type that is formed on the fourth insulating layer between the adjacent columnar gate electrodes of the fourth group,
wherein an SRAM circuit is configured by:
forming a third MOSFET of the first conductivity type that uses the third semiconductor layer as a channel;
forming a fourth MOSFET of the second conductivity type that uses the fourth semiconductor layer as a channel;
forming a fifth MOSFET that uses one of the fifth and sixth semiconductor layers of which the conductivity type is an n type as a channel;
forming a sixth MOSFET that uses one of the seventh and eighth semiconductor layers of which the conductivity type is an n type as a channel;
wherein the SRAM circuit is configured by:
connecting the adjacent columnar gate electrodes of the first group, one diffusion layer of the third MOSFET, one diffusion layer of the fourth MOSFET, and one diffusion layer of the sixth MOSFET together;
connecting the adjacent columnar gate electrodes of the second group, one diffusion layer of the first MOSFET, one diffusion layer of the second MOSFET, and one diffusion layer of the fifth MOSFET together;
connecting the other diffusion layer of the first MOSFET and the other diffusion layer of the third MOSFET are connected together;
connecting the other diffusion layer of the second MOSFET and the other diffusion layer of the fourth MOSFET together; and
connecting the adjacent columnar gate electrodes of the third group and the adjacent columnar gate electrodes of the fourth group together.

6. The semiconductor device according to claim 2, further comprising:
a plurality of columnar gate electrodes of a second group that are formed so as to be separated from one another in a row on the semiconductor substrate;
a second gate insulating film that covers side faces of the plurality of columnar gate electrodes of the second group;
a third semiconductor layer of the first conductivity type that is formed on the semiconductor substrate, between the columnar gate electrodes of the second group that are adjacent to each other;
a second insulating layer that is formed on the third semiconductor layer between the adjacent columnar gate electrodes of the second group; and
a fourth semiconductor layer of the second conductivity type that is formed on the second insulating layer between the adjacent columnar gate electrodes of the second group,
wherein a NAND circuit is configured by:
forming a third MOSFET of the first conductivity type that uses the third semiconductor layer as a channel;
forming a fourth MOSFET of the second conductivity type that uses the fourth semiconductor layer as a channel;
connecting the adjacent columnar gate electrodes of the first group to a first input terminal,
connecting the adjacent columnar gate electrodes of the second group to a second input terminal,
connecting both one diffusion layer of the first MOSFET and one diffusion layer of the second MOSFET to an output terminal,
connecting the other diffusion layer of the first MOSFET and one diffusion layer of the third MOSFET together,
connecting the other diffusion layer of the second MOSFET and one diffusion layer of the fourth MOSFET together, and
connecting the other diffusion layer of one of the third and fourth MOSFETs of which the conductivity type is a p type to the output terminal.

7. The semiconductor device according to claim 2, further comprising:
a plurality of columnar gate electrodes of a second group that are formed so as to be separated from one another in a row on the semiconductor substrate;
a second gate insulating film that covers side faces of the plurality of columnar gate electrodes of the second group;
a third semiconductor layer of the first conductivity type that is formed on the semiconductor substrate between the columnar gate electrodes of the second group that are adjacent to each other;
a second insulating layer that is formed on the third semiconductor layer between the adjacent columnar gate electrodes of the second group; and
a fourth semiconductor layer of the second conductivity type that is formed on the second insulating layer between the adjacent columnar gate electrodes of the second group,
wherein a NOR circuit is configured by:
forming a third MOSFET of the first conductivity type that uses the third semiconductor layer as a channel;
forming a fourth MOSFET of the second conductivity type that uses the fourth semiconductor layer as a channel;
connecting the adjacent columnar gate electrodes of the first group to a first input terminal,
connecting the adjacent columnar gate electrodes of the second group to a second input terminal,
connecting both one diffusion layer of the first MOSFET and one diffusion layer of the second MOSFET to an output terminal,
connecting the other diffusion layer of the first MOSFET and one diffusion layer of the third MOSFET together,
connecting the other diffusion layer of the second MOSFET and one diffusion layer of the fourth MOSFET together, and
connecting the other diffusion layer of one of the third and fourth MOSFETs of which the conductivity type is an n type to the output terminal.

8. The semiconductor device according to claim 2, further comprising:
a plurality of columnar gate electrodes of a second group that are formed so as to be separated from one another in a row on the semiconductor substrate;
a second gate insulating film that covers side faces of the plurality of columnar gate electrodes of the second group;
a third semiconductor layer of the first conductivity type that is formed on the semiconductor substrate between the columnar gate electrodes of the second group that are adjacent to each other;
a second insulating layer that is formed on the third semiconductor layer between the adjacent columnar gate electrodes of the second group;
a fourth semiconductor layer of the second conductivity type that is formed on the second insulating layer between the adjacent columnar gate electrodes of the second group;
a plurality of columnar gate electrodes of a third group that are formed so as to be separated from one another in a row on the semiconductor substrate;
a third gate insulating film that covers side faces of the plurality of columnar gate electrodes of the third group;
a fifth semiconductor layer of the first conductivity type that is formed on the semiconductor substrate between the columnar gate electrodes of the third group that are adjacent to each other;
a third insulating layer that is formed on the fifth semiconductor layer between the adjacent columnar gate electrodes of the third group;
a sixth semiconductor layer of the second conductivity type that is formed on the third insulating layer between the columnar gate electrodes of the third group that are adjacent to each other;
a plurality of columnar gate electrodes of a fourth group that are formed so as to be separated from one another in a row on the semiconductor substrate;
a fourth gate insulating film that covers side faces of the plurality of columnar gate electrodes of the fourth group;
a seventh semiconductor layer of the first conductivity type that is formed on the semiconductor substrate between the columnar gate electrodes of the fourth group that are adjacent to each other;
a fourth insulating layer that is formed on the seventh semiconductor layer between the adjacent columnar gate electrodes of the fourth group; and
an eighth semiconductor layer of the second conductivity type that is formed on the fourth insulating layer between the adjacent columnar gate electrodes of the fourth group,
wherein an SRAM circuit is configured by:
forming a third MOSFET of the first conductivity type that uses the third semiconductor layer as a channel;
forming a fourth MOSFET of the second conductivity type that uses the fourth semiconductor layer as a channel;
forming a fifth MOSFET that uses one of the fifth and sixth semiconductor layers of which the conductivity type is an n type as a channel;
forming a sixth MOSFET that uses one of the seventh and eighth semiconductor layers of which the conductivity type is an n type as a channel;
wherein the SRAM circuit is configured by:
connecting the adjacent columnar gate electrodes of the first group, one diffusion layer of the third MOSFET, one diffusion layer of the fourth MOSFET, and one diffusion layer of the sixth MOSFET together;
connecting the adjacent columnar gate electrodes of the second group, one diffusion layer of the first MOSFET, one diffusion layer of the second MOSFET, and one diffusion layer of the fifth MOSFET together;
connecting the other diffusion layer of the first MOSFET and the other diffusion layer of the third MOSFET are connected together;
connecting the other diffusion layer of the second MOSFET and the other diffusion layer of the fourth MOSFET together; and
connecting the adjacent columnar gate electrodes of the third group and the adjacent columnar gate electrodes of the fourth group together.

9. The semiconductor device according to claim 1,
wherein the first conductivity type is a p type and the second conductivity type is an n-type.

10. The semiconductor device according to claim 2,
wherein the first conductivity type is a p type and the second conductivity type is an n-type.

11. The semiconductor device according to claim 3,
wherein the first conductivity type is a p type and the second conductivity type is an n-type.

12. The semiconductor device according to claim 4,
wherein the first conductivity type is a p type and the second conductivity type is an n-type.

13. The semiconductor device according to claim 5,
wherein the first conductivity type is a p type and the second conductivity type is an n-type.

14. The semiconductor device according to claim 6,
wherein the first conductivity type is a p type and the second conductivity type is an n-type.

15. The semiconductor device according to claim 7,
wherein the first conductivity type is a p type and the second conductivity type is, an n-type.

16. The semiconductor device according to claim B,
wherein the first conductivity type is a p type and the second conductivity type is an n-type.

17. A method of manufacturing a semiconductor device, the method comprising:
forming a first insulating layer on a semiconductor substrate;
forming a first semiconductor layer on the first insulating layer;
forming a second insulating layer on the first semiconductor layer;
forming a second semiconductor layer, of which a conductivity type is different from that of the first semiconductor layer, on the second insulating layer;
forming a plurality of columnar opening portions that pass through the second semiconductor layer, and the second insulating layer, and the first semiconductor layer and have bottom faces reaching at least a top face of the first insulating layer so as to be separated from one another in a row;
forming a gate insulating film so as to cover bottom portions and side faces of the plurality of columnar opening portions, and
forming a plurality of columnar gate electrodes by burying a plurality of opening portions formed by the gate insulating film.

18. The method according to claim 17, wherein a film thickness of the first semiconductor layer and the second semiconductor layer is formed such that the film thickness of the semiconductor layer having a conductivity type of a p type is larger than that of the semiconductor layer having a conductivity type of an n type.

19. The method according to claim 17, wherein the conductivity type of the first semiconductor layer is a p-type, and the conductivity type of the second semiconductor layer is an n-type.

20. The method according to claim 18, wherein the conductivity type of the first semiconductor layer is a p-type, and the conductivity type of the second semiconductor layer is an n-type.
